(19) United States
(12) Patent Application Publication
(10) Pub. No.: US 2025/0166964 A1
(43) Pub. Date: May 22, 2025

(54) AUTOMATIC GRID FINGER DETECTION

(71) Applicant: FEI Company, Hillsboro, OR (US)

(72) Inventors: Tomas Onderlicka, Brno (CZ); Jaroslav Stárek, Krelov-Bruchotín (CZ); Jamie Dee Gravell, Beaverton, OR (US)

(21) Appl. No.: 18/947,905

(22) Filed: Nov. 14, 2024

Related U.S. Application Data
(60) Provisional application No. 63/601,422, filed on Nov. 21, 2023.

(51) Int. Cl. H01J 37/285

(52) U.S. Cl. CPC H01J 37/285; H01J 2237/2806; H01J 2237/2852

(57) ABSTRACT

Embodiments herein relate to sample support imaging and sample location identification at a sample support to be used for microscopy imaging. A system can comprise a memory that stores, and a processor that executes, computer executable components. The computer executable components can comprise a beam directing component that instructs a focused ion beam (FIB) device of a beam system to direct an ion beam at a sample support, and a field application component that affects secondary charged particles, emitted from the sample support due to the ion beam, by directing activation of a negative field from the beam system during application of the ion beam by the FIB device.

### CROSS REFERENCE TO RELATED APPLICATION

This is a nonprovisional claiming under 35 U.S.C. § 119 priority to and the benefit of U.S. Provisional Patent Application No. 63/601,422, filed on Nov. 21, 2023, entitled “Automatic Grid Finger Detection,” having docket number TP387247USPRV1, the entirety of which prior application is hereby incorporated by reference herein.

### BACKGROUND

Scientific instruments for use in material analysis can aid in determining the makeup and properties of an unknown composition. In one or more examples, a scientific instrument can provide location, manipulation and/or analysis at high resolution relative to a sample ranging in the hundred's of nanometers in one dimension, or less.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

It is noted that one or more drawings comprise one or more grey-scale images illustrating output images from a scientific instrument and are intended to depict the particular output that can be observed by a user entity.

FIG. 1 illustrates a block diagram of an example scientific instrument for performing operations, in accordance with one or more embodiments described herein.

FIG. 2 illustrates a flow diagram of an example method of performing operations using the scientific instrument of FIG. 1, in accordance with one or more embodiments described herein.

FIG. 3 illustrates a graphical user interface (GUI) that can be used in the performance of one or more of the methods described herein, in accordance with one or more embodiments described herein.

FIG. 4 illustrates a block diagram of an example computing device that can perform one or more of the methods disclosed herein, in accordance with one or more embodiments described herein.

FIG. 5 illustrates a block diagram of an example, non-limiting system that can facilitate a process for identification of an edge of a sample support by a system associated with a focused ion beam (FIB) device and an electron microscope (EM), in accordance with one or more embodiments described herein.

FIG. 6 illustrates a block diagram of another example, non-limiting system that can facilitate a process for identification of an edge of a sample support by a system associated with a focused ion beam (FIB) device and an electron microscope (EM), in accordance with one or more embodiments described herein.

FIG. 7A illustrates a block diagram of an example, non-limiting dual beam system comprising an EM and a FIB device, in accordance with one or more embodiments described herein.

FIG. 7B illustrates another block diagram of another example portion of a non-limiting dual beam system comprising an EM and a FIB device, in accordance with one or more embodiments described herein.

FIG. 8 provides a set of schematic illustrations of arrangement of aspects of the non-limiting system of FIG. 6 relative to one another, in accordance with one or more embodiments described herein.

FIG. 9 illustrates a set of image generations that can be performed by the non-limiting system of FIG. 6, in accordance with one or more embodiments described herein.

FIG. 10 illustrates a flow diagram of a set of processes that can be performed and/or instructed by the non-limiting system of FIG. 6, in accordance with one or more embodiments described herein.

FIG. 11 illustrates a set of image generations that can be performed and/or instructed by the non-limiting system of FIG. 6, and which illustrate results of use of the automatic locating system 602 of FIG. 6, in accordance with one or more embodiments described herein.

FIG. 12 illustrates flow diagram of one or more processes that can be performed by the automatic locating system of FIG. 6, in accordance with one or more embodiments described herein.

FIG. 13 illustrates a continuation of the flow diagram of FIG. 12 of one or more processes that can be performed by the automatic locating system of FIG. 6, in accordance with one or more embodiments described herein.

FIG. 14 illustrates flow diagram of one or more processes that can be performed by the automatic locating system of FIG. 6, in accordance with one or more embodiments described herein.

FIG. 15 illustrates a continuation of the flow diagram of FIG. 14 of one or more processes that can be performed by the automatic locating system of FIG. 6, in accordance with one or more embodiments described herein.

FIG. 16 illustrates flow diagram of one or more processes that can be performed by the automatic locating system of FIG. 6, in accordance with one or more embodiments described herein.

FIG. 17 illustrates a continuation of the flow diagram of FIG. 16 of one or more processes that can be performed by the automatic locating system of FIG. 6, in accordance with one or more embodiments described herein.

FIG. 18 illustrates a block diagram of example scientific instrument system in which one or more of the methods described herein can be performed, in accordance with one or more embodiments described herein.

FIG. 19 illustrates a block diagram of an example operating environment into which embodiments of the subject matter described herein can be incorporated.

FIG. 20 illustrates an example schematic block diagram of a computing environment with which the subject matter described herein can interact and/or be implemented at least in part.

### SUMMARY

The following presents a summary to provide a basic understanding of one or more embodiments described herein. This summary is not intended to identify key or critical elements, and/or to delineate scope of particular embodiments or scope of claims. Its sole purpose is to present concepts in a simplified form as a prelude to the more detailed description that is presented later. In one or more embodiments, systems, computer-implemented methods, apparatuses and/or computer program products described herein can provide process for identification of an edge of a sample support by a system associated with and/or comprising a focused ion beam (FIB) device and/or an electron microscope (EM).

In accordance with an embodiment, a system can comprise a memory that stores computer executable components, and a processor that executes the computer executable components. The computer executable components can comprise a beam directing component that instructs a focused ion beam (FIB) device of a beam system to direct an ion beam at a sample support, and a field application component that affects secondary charged particles emitted from the sample support due to the ion beam, by directing activation of a negative field from the beam system during application of the ion beam by the FIB device.

In accordance with another embodiment, a computer-implemented method can comprise scanning, by a system operatively coupled to a processor, a sample support with an ion beam of a focused ion beam (FIB) device of a beam system, generating, by the system, a repulsive charge that repulses, away from a detector of the beam system, a first set of secondary charged particles originating from the sample support based on the scanning, and allowing, by the system, a second set of secondary charged particles to be registered at the beam system despite the repulsive charge, the second set of secondary charged particles also originating from the sample support based on the scanning.

In accordance with still another embodiment, a computer program product facilitating a process for identification of an edge of a sample support by a system associated with a beam system comprising a focused ion beam (FIB) device and an electron microscope (EM), the program instructions executable by a processor to cause the processor to register, by the processor, secondary charged particles originating from a sample support aligned relative to the FIB device and the EM, and generate, by the processor, an image of the sample support, based on the registering, wherein the image comprises a first region having a greater signal bounded by a second region having a lesser signal, and wherein a boundary between the first region and the second region corresponds to an edge of the sample support.

The one or more embodiments disclosed herein can achieve improved performance relative to existing approaches. For example, based on application of a negative field during imaging by a dual beam system (that applies an ion beam to a sample and detecting generated secondary charged particles), an image having greater area of greater contrasting signal can be generated. This can allow for more efficient and more accurate identification of an edge of a sample support being imaged by the dual beam system, as compared to existing techniques. In turn, this can allow for more accurate placement of a sample on and/or at the sample support, as compared to existing techniques.

The placement of the sample can be made more efficient and accurate because an attachment region on the sample support can be more accurately identified, in view of the one or more embodiments described herein. Further, a reduced quantity and/or smaller area of sample substrate can be removed from the identified region due to the more efficient and accurate identification of the attachment region on the sample support, as compared to existing techniques.

In one or more embodiments described herein, identification of an attachment region of a sample support can be made automatic to thereby reduce and/or eliminate manual identification of the attachment region. In turn, this can reduce location identification error, increase location identification accuracy and/or time to successful location identification than can be provided by existing techniques.

Further, the embodiments described herein can be adapted to work with sample supports have various different shaped surfaces, a sample support in combination with a background and/or non-sample support applications such as, but not limited to, imaging of a sample.

### DETAILED DESCRIPTION

The following detailed description is merely illustrative and is not intended to limit embodiments and/or application or utilization of embodiments. Furthermore, there is no intention to be bound by any expressed or implied information presented in the preceding Summary section, or in the Detailed Description section. One or more embodiments are now described with reference to the drawings, wherein like reference numerals are utilized to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Various operations can be described as multiple discrete actions or operations in turn, in a manner that is most helpful in understanding the subject matter disclosed herein. However, the order of description should not be construed as to imply that these operations are necessarily order dependent. In particular, these operations can be performed in an order different from the order of presentation. Operations described can be performed in a different order from the described embodiment. Various additional operations can be performed, and/or described operations can be omitted in additional embodiments.

Turning now to the subject of material analysis and to the one or more embodiments described herein, one method of obtaining composition imaging can be electron microscopy where a sample is targeted by an ion source, ultimately resulting in an emission of (and/or generation of) secondary charged particles, such as secondary electrons and/or secondary ions, that can be detected and registered to then generate an image of the sample.

Set up for this type of imaging, with existing techniques, presently relies on manual alignment of a dual beam system relative to a sample support, whereby a sample is subsequently attached to the sample support based on the identification of an attachment region of the sample support using the dual beam system. The dual beam system generally can comprise a focused ion beam (FIB) device and an electron microscope, such as a scanning electron microscope or transmission electron microscope (S/TEM).

Existing techniques employed for identification of the attachment region can comprise manual angle alignment, manual identification of weak contrast change from imaging, manually driving an attachment tool (e.g., a needle, micromanipulator and/or nanomanipulator) into the sample support, which can damage or move the sample support, detecting a shadow of the sample or attachment tool when close to the sample support as a means of relative location identification (e.g., manually and/or using image processing). Each of these techniques relies on indirect and/or interpolated identification of an attachment region of a sample support.

In combination with these techniques, a repelling field, such as a positive field, is applied relative to a secondary charged particle detector to pull the secondary charged particles (emitted due to use of an ion beam from the FIB) towards the detector. Detection and subsequent registering of the secondary charged particles can allow for image generation of the sample support.

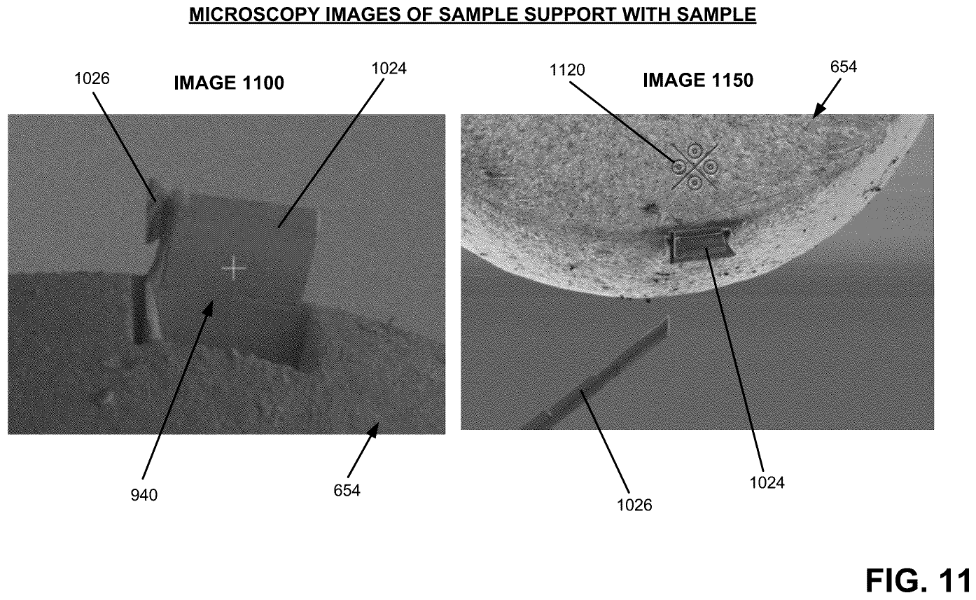

However, in view of the inaccurate and manual nature of these existing techniques, identification of an attachment region is slow, prone to error, and can be subjective due to user entity identification of the attachment region. Further, exact angling of the surface of the attachment region can be inaccurately and/or non-precisely determined due to the same slow, error prone or subjective identification. As a result, it can be difficult or impossible to accurately attach a sample, such as a lamella, to the sample support with a known angle (e.g., a beta angle such as of about 10 degrees, as shown at image 1100 of FIG. 11). It is noted that such angle can employed to reduce curtaining of the sample during thinning and/or polishing of the sample while the sample is attached to the sample support.

Additionally, regarding the existing techniques, inaccurate identification of attachment region can lead to a need to remove (e.g., by trenching) a greater quantity of material of the sample support prior to attachment of the sample. That is, material is removed such as to not interfere with attachment of the sample or imaging of the sample when attached to the sample support.

Further regarding the existing techniques, none are suitable, accurate enough and/or objective enough for automation (e.g., as an automated identification technique).

As another result of existing inaccurate and manual attachment region identification techniques, welding of a sample to the sample support can be inaccurate, resulting in minimal attachment that is not robust and can allow for movement of the sample during sample modification and/or sample imaging, both of which are undesirable.

To account for one or more inabilities or deficiencies of existing frameworks (e.g., existing attachment region identification frameworks), one or more embodiments are described herein that can employ a unique attachment region identification framework to achieve high information gathering relative to the sample support, resulting in more accurate identification of a smaller and more exact attachment region, and further can employ an automated approach. This attachment region identification framework can comprise application of a negative field, such as at and/or adjacent to a secondary charged particle detector (e.g., a cage suction tube of a charged particle detector), during scanning by an ion beam of a FIB device of a dual beam system. This can result in repulsion of at least some secondary charged particles being emitted from the sample support due to the use of the ion beam. While counterintuitive, a reduced detection of secondary charged particles relative to only a partial surface area of the sample support can allow for enhanced and automated imaging using automatic locating system embodiments described herein.

Discussion next turns to a general discussion of one or more scientific instrument systems disclosed herein, as well as related methods, computing devices, and computer-readable media. For example, in one or more embodiments, a system can comprise a memory that stores computer executable components and a processor that executes the computer executable components stored in the memory. The computer executable components comprise a beam directing component that instructs a focused ion beam (FIB) device to direct an ion beam at a sample support, and a field application component that affects secondary charged particles, emitted from the sample support due to the ion beam, by directing activation of a negative field from an electron microscope (EM) during application of the ion beam by the FIB device.

As indicated above, the one or more embodiments disclosed herein can achieve improved performance relative to existing approaches. For example, based on application of a negative field, such as to a conductive component, such as a screen, cage or tube, such as being arranged adjacent to and/or coupled to a charged particle detector, during imaging by a dual beam system (that applies an ion beam to a sample and detecting generated secondary charged particles), an image having greater area of greater contrasting signal can be generated. This can allow for more efficient and/or more accurate identification of an edge of a sample support being imaged by the dual beam system, as compared to existing techniques. In turn, this can allow for more accurate placement of a sample on and/or at the sample support, as compared to existing techniques. In connection with sample placement, a reduced quantity and/or smaller area of sample substrate can be removed from the identified region due to the more efficient and accurate identification of the attachment region on the sample support, as compared to existing techniques.

Therefore, the embodiments disclosed herein provide improvements to scientific instrument technology (e.g., improvements in the computer technology supporting such scientific instruments, among other improvements), which can be employed in various fields including microscopic imaging, optics, signal processing, spectroscopy, and nuclear magnetic resonance (NMR), without being limited thereto.

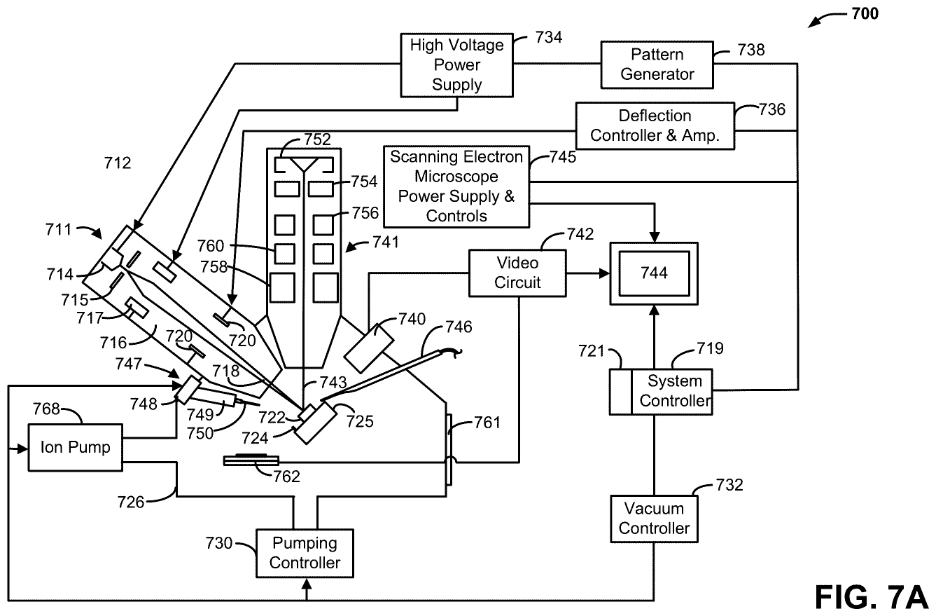

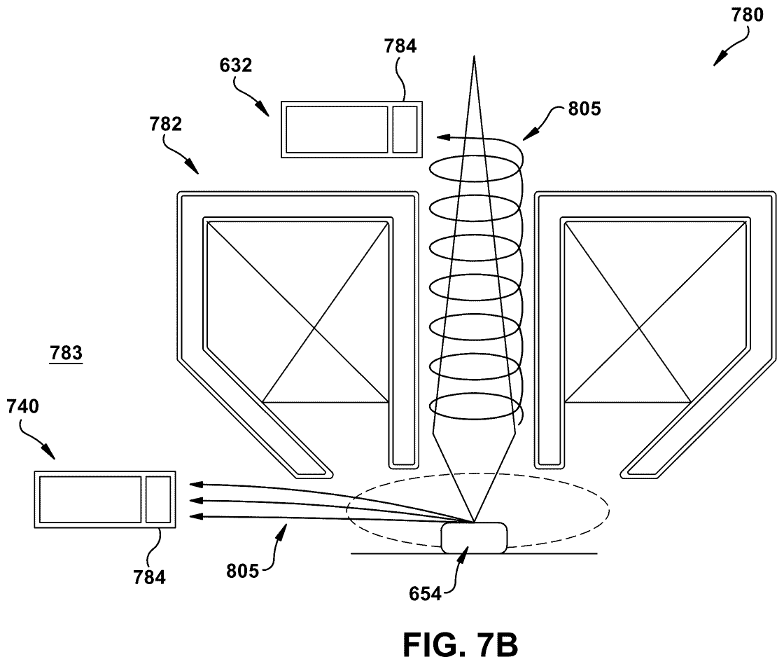

Various ones of the embodiments disclosed herein can improve upon existing approaches to achieve the technical advantages of increased contrast imaging, narrower attachment region identification, reduced sample support modification for sample attachment and/or more stable sample attachment. That is, use of the microscopic imaging preparation framework provided herein can allow for automatic and more specific location of an attachment region of a sample support prior to attachment of the sample to the sample support, and thus also prior to microscopic imaging of the sample. The one or more frameworks employed herein can employ an automatic locating system, as described herein, along with a same dual beam system as can be used for the subsequent microscopic imaging of the sample. It is noted that exemplary dual beam systems are described in detail below relative to FIGS. 7A and 7B.

The above-mentioned technical advantages are not achievable by routine and existing approaches, and all user entities of systems including such embodiments can benefit from these advantages (e.g., by assisting the user entity in the performance of a technical task, such as identification of an attachment region of a sample support, by means of an imaging framework discussed herein).

The technical features of the embodiments disclosed herein (e.g., application of the negative field and generation of a resulting image of a sample support having high contrasted areas, with both being performed automatically) are thus decidedly unconventional in the field of microscopic imaging, in addition to the fields of optics, signal processing, spectroscopy, and/or NMR, without being limited thereto, as are combinations of the features of the embodiments disclosed herein.

As discussed further herein, various aspects of the embodiments disclosed herein can improve the functionality of a computer itself. That is, the computational and user interface features disclosed herein do not involve only the collection and comparison of information but instead apply new analytical and technical techniques to change the operation of the computer-analysis of material compounds. For example, based on the application of the negative field, causing a repulsive bias, a reduced quantity of secondary charged particles corresponding to at least one surface of the sample support can be received at a detector of the dual beam system. Based on this reduced receipt of secondary charged particles, an image of the sample support comprising highly contrasted areas can be generated. These processes can all be performed automatically because the imaging of the sample support does not rely on a manual input, as do existing frameworks. Accordingly, a corresponding computer-directed process of sample support imaging itself can be made easier and more efficient through reduction of detection of secondary charged particles, such as secondary electrons and/or secondary ions, for one or more surfaces of the sample support (or other environment surfaces) relative to one or more other surfaces of the sample support (or other environment surfaces). As such, a non-limiting system described herein, comprising an automatic locating system, can be self-improving.

The present disclosure thus introduces functionality that neither an existing computing device, nor a human, could perform. Rather, such existing computing devices would instead require manual input to accurately identify an attachment region of a sample support, or simply would be unable to identify an attachment region of a sample support as accurately as the one or more embodiments described herein due to limited contrast imaging of the sample support. In view of the time, energy, human error, and lack of automation involved, in addition to the lack of accurate sample attachment, it is not practical to operate within the confines of existing approaches.

Accordingly, the embodiments of the present disclosure can serve any of a number of technical purposes, such as controlling a specific technical system or process; determining from measurements how to control a machine; digital audio, image, or video enhancement or analysis; separation of material sources in a mixed signal; generating data for reliable and/or efficient transmission or storage; providing estimates and confidence intervals for material samples; or providing a faster processing of sensor data. In particular, the present disclosure provides technical solutions to technical problems, including, but not limited to, accurate and repeatable attachment region identification, accurate and repeatable sample attachment, and ability to perform accurate subsequent processes, such as sample thinning or polishing and/or sample imaging, resulting in a faster, more thorough and/or more efficient processing of material samples.

The embodiments disclosed herein thus provide improvements to material analysis technology (e.g., improvements in the computer technology supporting material analysis, among other improvements).

As used herein, the phrase “based on” should be understood to mean “based at least in part on,” unless otherwise specified.

As used herein, the term “component” can refer to an atomic element, molecular element, phase of an atomic or molecular element, or combination thereof.

As used herein, the terms “compound” and “precursor” can be used interchangeably.

As used herein, the term “data” can comprise metadata.

As used herein, the terms “entity,” “requesting entity,” and “user entity” can refer to a machine, device, component, hardware, software, smart device, party, organization, individual and/or human.

One or more embodiments are now described with reference to the drawings, where like referenced numerals are used to refer to like drawing elements throughout. In the following description, for purposes of explanation, numerous specific details are set forth in order to provide a more thorough understanding of the one or more embodiments. It is evident in various cases, however, that the one or more embodiments can be practiced without these specific details.

Further, it should be appreciated that the embodiments depicted in one or more figures described herein are for illustration only, and as such, the architecture of embodiments is not limited to the systems, devices and/or components depicted therein, nor to any particular order, connection and/or coupling of systems, devices and/or components depicted therein.

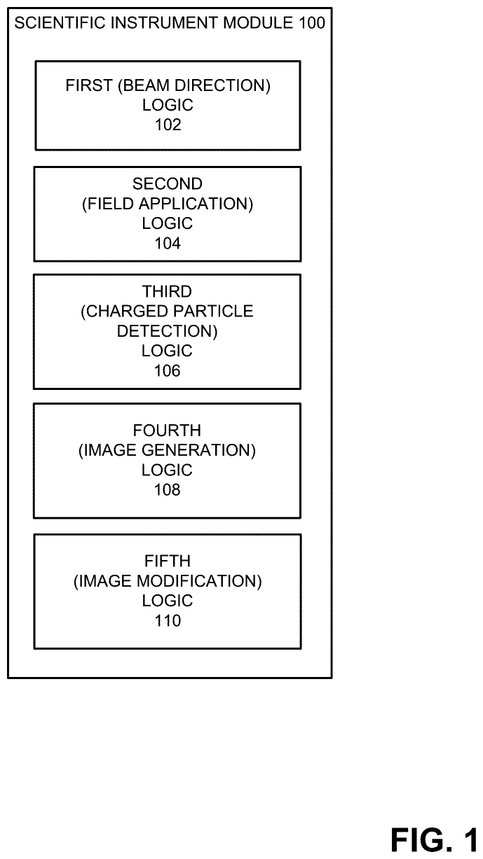

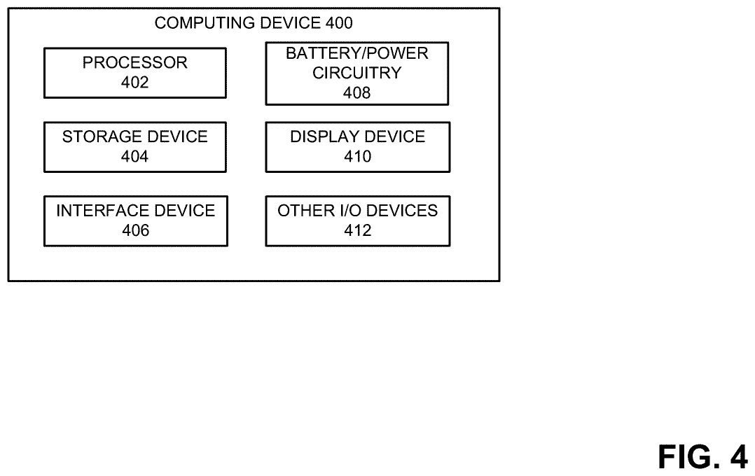

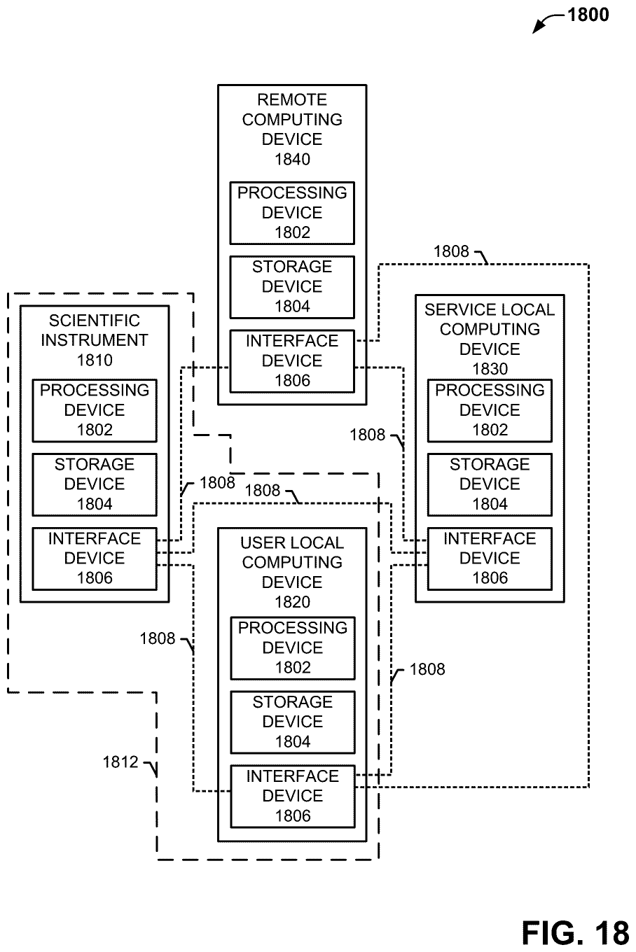

Turning now in particular to the one or more figures, and first to FIG. 1, illustrated is a block diagram of a scientific instrument module 100 for preparation and setup related to performing material analysis operations using a microscopic imaging technique, in accordance with various embodiments described herein. The scientific instrument module 100 can be implemented by circuitry (e.g., including electrical and/or optical components), such as a programmed computing device. The logic of the scientific instrument module 100 can be included in a single computing device or can be distributed across multiple computing devices that are in communication with each other as appropriate. Examples of computing devices that can, singly or in combination, implement the scientific instrument module 100 are discussed herein with reference to the computing device 400 of FIG. 4, and examples of systems of interconnected computing devices, in which the scientific instrument module 100 can be implemented across one or more of the computing devices, is discussed herein with reference to the scientific instrument system 1800 of FIG. 18.

The scientific instrument module 100 can function in correspondence with an FIB (focused ion beam) device and an EM (electron microscope), such as which are combined in a dual beam system. The scientific instrument module 100 can include first logic 102, second logic 104, third logic 106, fourth logic 108 and fifth logic 110. As used herein, the term “logic” can include an apparatus that is to perform a set of operations associated with the logic. For example, any of the logic elements included in the module 100 can be implemented by one or more computing devices programmed with instructions to cause one or more processing devices of the computing devices to perform the associated set of operations. In a particular embodiment, a logic element can include one or more non-transitory computer-readable media having instructions thereon that, when executed by one or more processing devices of one or more computing devices, cause the one or more computing devices to perform the associated set of operations. As used herein, the term “module” can refer to a collection of one or more logic elements that, together, perform a function associated with the module. Different ones of the logic elements in a module can take the same form or can take different forms. For example, some logic in a module can be implemented by a programmed general-purpose processing device, while other logic in a module can be implemented by an application-specific integrated circuit (ASIC). In another example, different ones of the logic elements in a module can be associated with different sets of instructions executed by one or more processing devices. A module can omit one or more of the logic elements depicted in the associated drawing; for example, a module can include a subset of the logic elements depicted in the associated drawing when that module is to perform a subset of the operations discussed herein with reference to that module.

The first logic 102 can cause and/or direct the receiving, finding, locating and/or alignment of an ion beam of an FIB device to a support grid, such as comprising one or more sample supports. That is, the first logic 102 can cause alignment of the ion beam of the FIB device with the support grid, more generally.

The second logic 104 can cause and/or direct application of a negative field to at least a portion of a sample grid comprising a sample support for being imaged. That is, the second logic 104 can direct generation of the negative field by an EM, such as of a dual beam system also comprising the FIB device mentioned relative to the first logic 102. For example, a bias voltage can be applied to a component adjacent to or coupled to a receiving end of a detector, which can attract and/or reflect charged particles as intended to implement the improved imaging disclosed herein.

The third logic 106 can cause and/or direct the detection of secondary charged particles emitted and/or generated relative to the sample support in response to application of the ion beam (first logic 102) to the sample support. That is, the third logic 106 can, based on the functioning of the first logic 102 and the second logic 104, execute the detection of secondary charged particles.

The fourth logic 108 can cause and/or direct generation of an image of the sample support. That is, based on the detection (third logic 106) the fourth logic 108 can generate the image.

The fifth logic 110 can cause and/or direct modification of the image generated by the fourth logic 108. That is, the fifth logic 110 can cause particular identification of a boundary being contrasted portions of the sample support, which boundary can comprise an attachment region for a sample to be attached to the sample support.

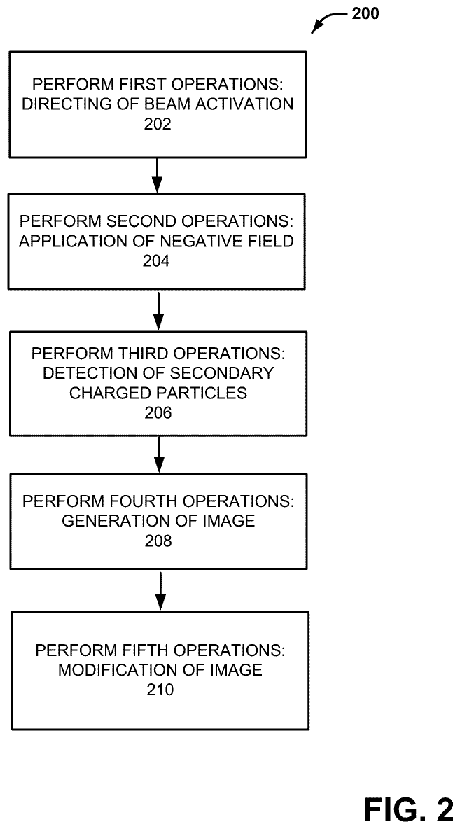

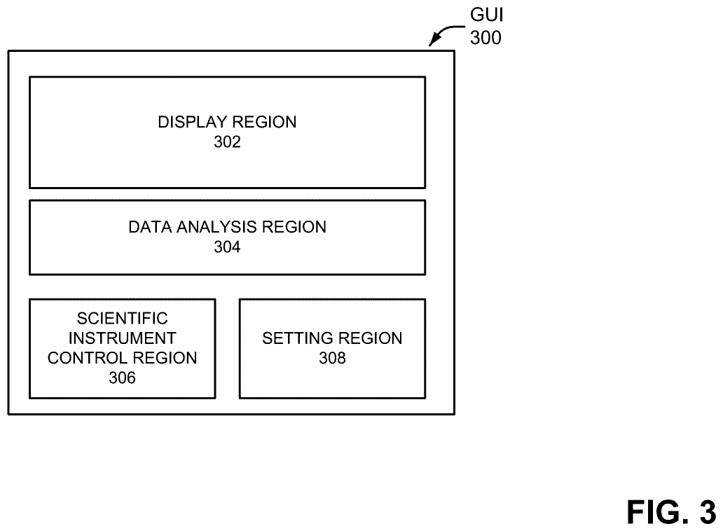

FIG. 2 illustrates a flow diagram of a method 200 of performing operations, by the scientific instrument module 100, in accordance with various embodiments. Although the operations of the method 200 can be illustrated with reference to particular embodiments disclosed herein (e.g., the scientific instrument module 100 discussed herein with reference to FIG. 1, the GUI 300 discussed herein with reference to FIG. 3, the computing device 400 discussed herein with reference to FIG. 4, and/or the scientific instrument system 1800 discussed herein with reference to FIG. 18), the method 200 can be used in any suitable setting to perform any suitable operations. Operations are illustrated once each and in a particular order in FIG. 2, but the operations can be reordered and/or repeated as desired and appropriate (e.g., different operations performed can be performed in parallel, as suitable).

At 202, first operations can be performed. For example, the first logic 102 of the module 100 can perform the first operations 202. The first operations 202 can include directing and/or causing alignment and/or activation of an ion beam from the FIB device.

At 204, second operations can be performed. For example, the second logic 104 of the module 100 can perform the second operations 204. The second operations 204 can include directing and/or causing application of the negative field from the EM, although it is appreciated that the negative field can be generated by any other aspect, such as the dual beam system, the FIB device, a portion of the dual beam system separate from the FIB device and EM, and/or a device separate from the dual beam system. In one or more examples, the negative field can be applied to a conductive component, such as a screen or tube, arranged adjacent to or coupled to a charged particle detector of the EM.

At 206, third operations can be performed. For example, the third logic 106 of the module 100 can perform the third operations 206. The third operations 206 can include directing and/or causing detection of the aforementioned secondary charged particles caused by application of the ion beam to the sample support.

At 208, fourth operations can be performed. For example, the fourth logic 108 of the module 100 can perform the fourth operations 208. The fourth operations 208 can include directing and/or causing generation of an image of the sample support based on the detection of the secondary charged particles.

At 210, fifth operations can be performed. For example, the fifth logic 110 of the module 100 can perform the fifth operations 210. The fifth operations 210 can include directing and/or causing modification of the generated image, such as to highlight and/or identify a boundary between highly contrasted regions of the generated image.

The scientific instrument methods disclosed herein can include interactions with a user entity (e.g., via the user local computing device 1820 discussed herein with reference to FIG. 18). These interactions can include providing information to the user entity (e.g., information regarding the operation of a scientific instrument such as the scientific instrument 1810 of FIG. 18, information regarding a sample being analyzed or other test or measurement performed by a scientific instrument, information retrieved from a local or remote database, or other information) or providing an option for a user entity to input commands (e.g., to control the operation of a scientific instrument such as the scientific instrument 1810 of FIG. 18, or to control the analysis of data generated by a scientific instrument), queries (e.g., to a local or remote database), or other information. In some embodiments, these interactions can be performed through a graphical user interface (GUI) that includes a visual display on a display device (e.g., the display device 410 discussed herein with reference to FIG. 4) that provides outputs to the user entity and/or prompts the user entity to provide inputs (e.g., via one or more input devices, such as a keyboard, mouse, trackpad, or touchscreen, included in the other I/O devices 412 discussed herein with reference to FIG. 4). The scientific instrument system 1800 disclosed herein can include any suitable GUIs for interaction with a user entity.

Turning next to FIG. 3, depicted is an example GUI 300 that can be used in the performance of some or all of the methods described herein, in accordance with various embodiments described herein. As noted above, the GUI 300 can be provided on a display device (e.g., the display device 410 discussed herein with reference to FIG. 4) of a computing device (e.g., the computing device 400 discussed herein with reference to FIG. 4) of a scientific instrument system (e.g., the scientific instrument system 1800 discussed herein with reference to FIG. 18), and a user entity can interact with the GUI 300 using any suitable input device (e.g., any of the input devices included in the other I/O devices 412 discussed herein with reference to FIG. 4) and input technique (e.g., movement of a cursor, motion capture, facial recognition, gesture detection, voice recognition, actuation of buttons, etc.).

The GUI 300 can include a data display region 302, a data analysis region 304, a scientific instrument control region 306, and a settings region 308. The particular number and arrangement of regions depicted in FIG. 3 is merely illustrative, and any number and arrangement of regions, including any desired features thereof, can be included in a GUI 300.

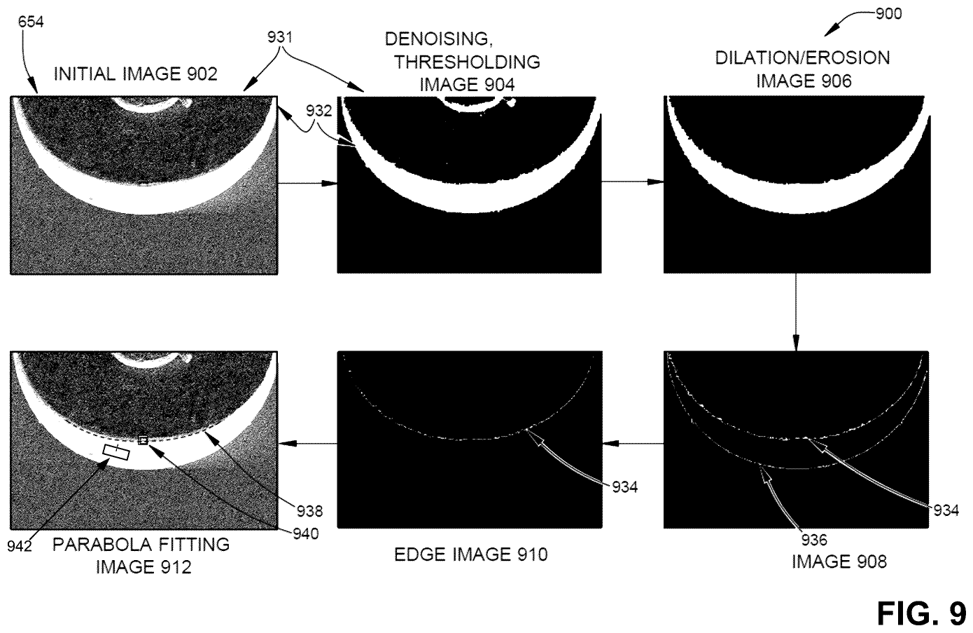

The data display region 302 can display data generated by a scientific instrument (e.g., the scientific instrument 1810 discussed herein with reference to FIG. 18). For example, the data display region 302 can display one or more output images 902-912 (FIG. 9) and/or one or ore text, graphs, charts, matrices and/or spectra, without being limited thereto.

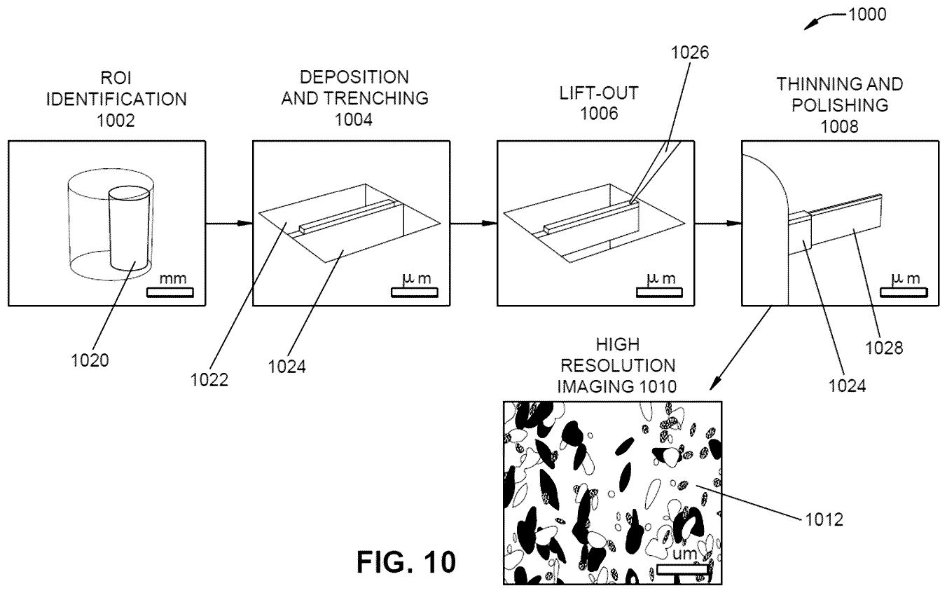

The data analysis region 304 can display the results of data analysis (e.g., the results of analyzing the data illustrated in the data display region 302 and/or other data). For example, the data analysis region 304 can display one or more results of sample imaging, such as corresponding to high resolution imaging 1010 (FIG. 10). In one or more cases, the data analysis region 304 can display a list, flow chart or other schematic of acquisition actions taken and/or recommended relative to an experiment. In one or more embodiments, the data display region 302 and the data analysis region 304 can be combined in the GUI 300 (e.g., to include data output from a scientific instrument, and some analysis of the data, in a common graph or region).

The scientific instrument control region 306 can include options that allow the user entity to control a scientific instrument (e.g., the scientific instrument 1810 discussed herein with reference to FIG. 18). For example, the scientific instrument control region 306 can include one or more controls for inputting one or more metrics of interest.

The settings region 308 can include options that allow the user entity to control the features and functions of the GUI 300 (and/or other GUIs) and/or perform common computing operations with respect to the data display region 302 and data analysis region 304 (e.g., saving data on a storage device, such as the storage device 404 discussed herein with reference to FIG. 4, sending data to another user entity, labeling data, etc.). For example, the settings region 308 can include one or more options to alter color, fill or format of illustrations, such as an illustration related to images of FIG. 9 or FIG. 10.

As noted above, the scientific instrument module 100 can be implemented by one or more computing devices. Accordingly, discussion next turns to FIG. 4, which illustrates a block diagram of a computing device 400 that can perform some or all of the scientific instrument methods disclosed herein, in accordance with various embodiments. In one or more embodiments, the scientific instrument module 100 can be implemented by a single computing device 400 or by multiple computing devices 400. Further, as discussed below, a computing device 400 (or multiple computing devices 400) that implements the scientific instrument module 100 can be part of one or more of the scientific instrument 1810, the user local computing device 1820, the service local computing device 1830, or the remote computing device 1840 of FIG. 18.

The computing device 400 of FIG. 4 is illustrated as having a number of components, but any one or more of these components can be omitted or duplicated, as suitable for the application and setting. As illustrated, these components can include one or more of a processor 402, storage device 404, interface device 406, battery/power circuitry 408, display device 410 and other input/output (I/O) devices 412, as will be described below.

In one or more embodiments, one or more of the components included in the computing device 400 can be attached to one or more motherboards and enclosed in a housing (e.g., including plastic, metal, and/or other materials). In one or more embodiments, some these components can be fabricated onto a single system-on-a-chip (SoC) (e.g., an SoC can include one or more processors 402 and one or more storage devices 404). Additionally, in one or more embodiments, the computing device 400 can omit one or more of the components illustrated in FIG. 4. In one or more embodiments, the computing device 400 can include interface circuitry (not shown) for coupling to the one or more components using any suitable interface (e.g., a Universal Serial Bus (USB) interface, a High-Definition Multimedia Interface (HDMI) interface, a Controller Area Network (CAN) interface, a Serial Peripheral Interface (SPI) interface, an Ethernet interface, a wireless interface, or any other appropriate interface). For example, the computing device 400 can omit a display device 410, but can include display device interface circuitry (e.g., a connector and driver circuitry) to which a display device 410 can be coupled.

The computing device 400 can include the processor 402 (e.g., one or more processing devices). As used herein, the term “processing device” can refer to any device or portion of a device that processes electronic data from registers and/or memory to transform that electronic data into other electronic data that can be stored in registers and/or memory. The processor 402 can include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The computing device 400 can include a storage device 404 (e.g., one or more storage devices). The storage device 404 can include one or more memory devices such as random access memory (RAM) (e.g., static RAM (SRAM) devices, magnetic RAM (MRAM) devices, dynamic RAM (DRAM) devices, resistive RAM (RRAM) devices, or conductive-bridging RAM (CBRAM) devices), hard drive-based memory devices, solid-state memory devices, networked drives, cloud drives, or any combination of memory devices. In one or more embodiments, the storage device 404 can include memory that shares a die with a processor 402. In such an embodiment, the memory can be used as cache memory and can include embedded dynamic random-access memory (eDRAM) or spin transfer torque magnetic random-access memory (STT-MRAM), for example. In one or more embodiments, the storage device 404 can include non-transitory computer readable media having instructions thereon that, when executed by one or more processing devices (e.g., the processor 402), cause the computing device 400 to perform any appropriate ones of or portions of the methods disclosed herein.

The computing device 400 can include an interface device 406 (e.g., one or more interface devices 406). The interface device 406 can include one or more communication chips, connectors, and/or other hardware and software to govern communications between the computing device 400 and other computing devices. For example, the interface device 406 can include circuitry for managing wireless communications for the transfer of data to and from the computing device 400. The term “wireless” and its derivatives can be used to describe circuits, devices, systems, methods, techniques, communications channels, etc., that can communicate data through the use of modulated electromagnetic radiation through a nonsolid medium. The term does not imply that the associated devices do not contain any wires, although in one or more embodiments the associated devices might not contain any wires. Circuitry included in the interface device 406 for managing wireless communications can implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). In one or more embodiments, circuitry included in the interface device 406 for managing wireless communications can operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. In one or more embodiments, circuitry included in the interface device 406 for managing wireless communications can operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). In one or more embodiments, circuitry included in the interface device 406 for managing wireless communications can operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. In one or more embodiments, the interface device 406 can include one or more antennas (e.g., one or more antenna arrays) to receipt and/or transmission of wireless communications.

In one or more embodiments, the interface device 406 can include circuitry for managing wired communications, such as electrical, optical, or any other suitable communication protocols. For example, the interface device 406 can include circuitry to support communications in accordance with Ethernet technologies. In one or more embodiments, the interface device 406 can support both wireless and wired communication, and/or can support multiple wired communication protocols and/or multiple wireless communication protocols. For example, a first set of circuitry of the interface device 406 can be dedicated to shorter-range wireless communications such as Wi-Fi or Bluetooth, and a second set of circuitry of the interface device 406 can be dedicated to longer-range wireless communications such as global positioning system (GPS), EDGE, GPRS, CDMA, WiMAX, LTE, EV-DO, or others. In one or more embodiments, a first set of circuitry of the interface device 406 can be dedicated to wireless communications, and a second set of circuitry of the interface device 406 can be dedicated to wired communications.

The computing device 400 can include battery/power circuitry 408. The battery/power circuitry 408 can include one or more energy storage devices (e.g., batteries or capacitors) and/or circuitry for coupling components of the computing device 400 to an energy source separate from the computing device 400 (e.g., AC line power).

The computing device 400 can include a display device 410 (e.g., multiple display devices). The display device 410 can include any visual indicators, such as a heads-up display, a computer monitor, a projector, a touchscreen display, a liquid crystal display (LCD), a light-emitting diode display, or a flat panel display.

The computing device 400 can include other input/output (I/O) devices 412. The other I/O devices 412 can include one or more audio output devices (e.g., speakers, headsets, earbuds, alarms, etc.), one or more audio input devices (e.g., microphones or microphone arrays), location devices (e.g., GPS devices in communication with a satellite-based system to receive a location of the computing device 400, as known in the art), audio codecs, video codecs, printers, sensors (e.g., thermocouples or other temperature sensors, humidity sensors, pressure sensors, vibration sensors, accelerometers, gyroscopes, etc.), image capture devices such as cameras, keyboards, cursor control devices such as a mouse, a stylus, a trackball, or a touchpad, bar code readers, Quick Response (QR) code readers, or radio frequency identification (RFID) readers, for example.

The computing device 400 can have any suitable form factor for its application and setting, such as a handheld or mobile computing device (e.g., a cell phone, a smart phone, a mobile internet device, a tablet computer, a laptop computer, a netbook computer, an ultrabook computer, a personal digital assistant (PDA), an ultra mobile personal computer, etc.), a desktop computing device, or a server computing device or other networked computing component.

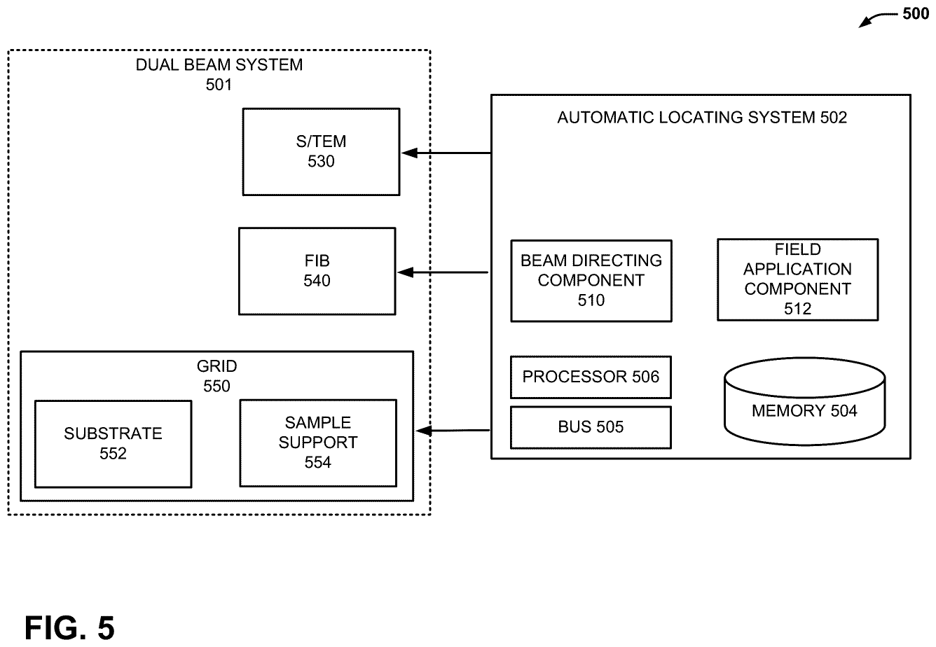

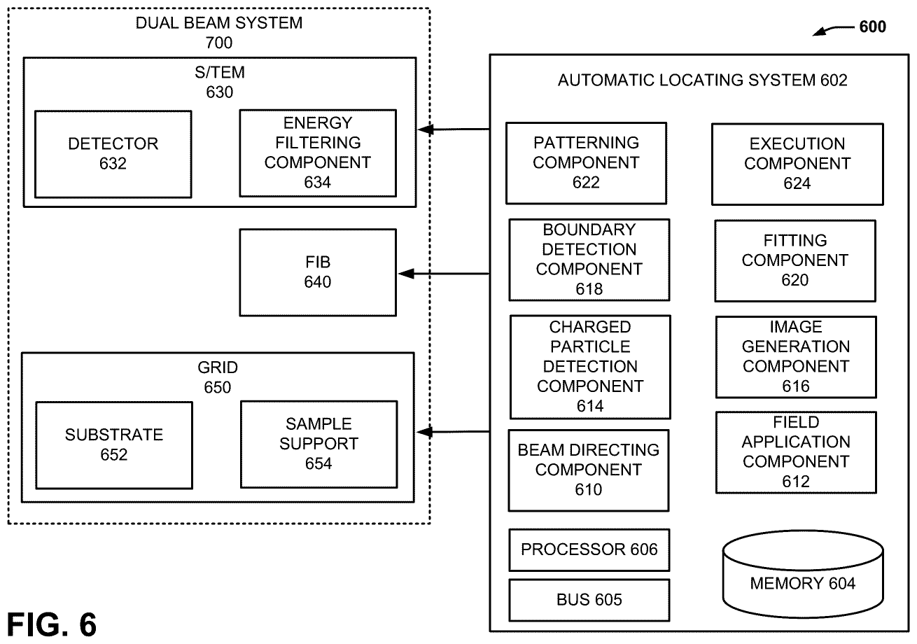

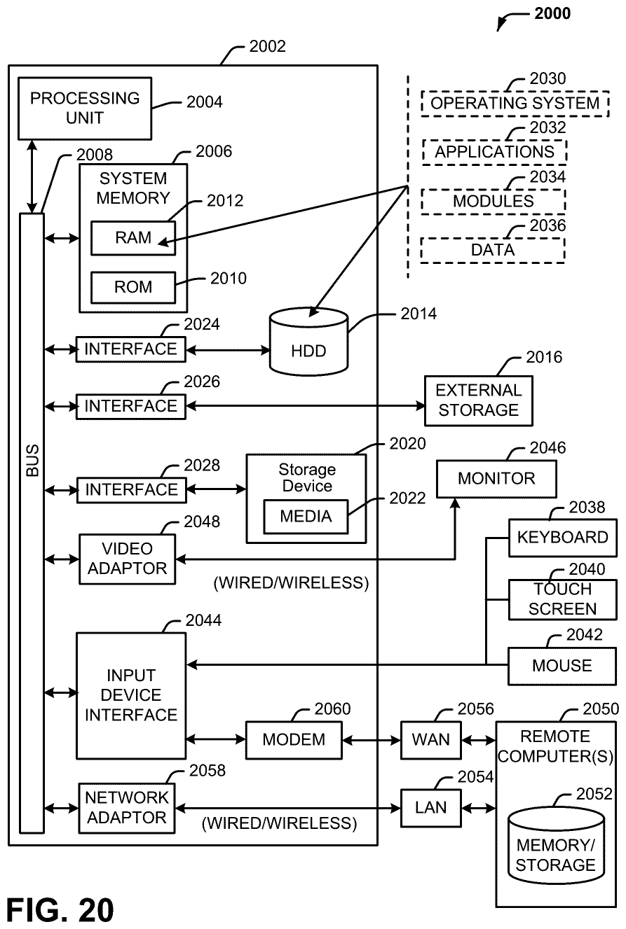

Referring next to FIGS. 5 and 6, in one or more embodiments, the non-limiting systems 500 and/or 600 illustrated at FIGS. 5 and 6, and/or systems thereof, can further comprise one or more computer and/or computing-based elements described herein with reference to a computing environment, such as the computing environment 2000 illustrated at FIG. 20. In one or more described embodiments, computer and/or computing-based elements can be used in connection with implementing one or more of the systems, devices, components and/or computer-implemented operations shown and/or described in connection with FIGS. 5 and/or 6 and/or with other figures described herein.

Turning first to FIG. 5, the figure illustrates a block diagram of an example, non-limiting system 500 that can comprise an automatic locating system 502 and a dual beam system 501. The automatic locating system 502 can facilitate identification of an attachment region, such as an edge, of a sample support by a system associated with a focused ion beam (FIB) device and an electron microscope (EM), such as of the dual beam system 501.

In one or more embodiments, the automatic locating system 502 can be at least partially comprised by the computing device 400.

In one or more embodiments, the automatic locating system 502 can at least partially comprise the dual beam system 501.

In one or more embodiments, the dual beam system 501 can at least partially comprise the automatic locating system 502.

It is noted that the automatic locating system 502 is only briefly detailed to provide but a lead-in to a more complex and/or more expansive automatic locating system 602 as illustrated at FIG. 6. That is, further detail regarding processes that can be performed by one or more embodiments described herein will be provided below relative to the non-limiting system 600 of FIG. 6.

Still referring to FIG. 5, the automatic locating system 502 can comprise at least

a memory 504, bus 505, processor 506, beam directing component 510 and field application component 512. The processor 506 can be the same as the processor 402, comprised by the processor 402 or different therefrom. The memory 504 can be the same as the storage device 404, comprised by the storage device 404 or different therefrom.

Using the above-noted components, the automatic locating system 502 can facilitate a process to first generally identify a sample support 554, and secondarily, identify an attachment region at the sample support 554 for which to attach a sample to be imaged using microscopic imaging.

Generally, the sample support 554 can be one of one or more sample supports 554 of a grid system 550 comprising the one or more sample supports 554 coupled to a substrate 552.

Generally, the beam directing component 510 can instruct (e.g., direct and/or cause) a focused ion beam (FIB) device 540 to direct an ion beam at a sample support. The instruction can be by any suitable means between the automatic locating system 502 and the dual beam system 501.

In connection with activation of the ion beam, the field application component 512 can affect secondary charged particles, emitted from the sample support 554 due to the ion beam, by directing activation of a negative field relative to the electron microscope (EM) (e.g., S/TEM 530) during application of the ion beam by the FIB device 540. In one or more embodiments, the negative field can be generated by an element of the S/TEM 530. In one or more other embodiments, the negative field can additionally, and/or alternatively, generated by the FIB device 540, another element of the dual beam system 501, the automatic locating system 502 directly, and/or another element communicatively coupled to the dual beam system 501 and/or automatic locating system 502. For example, and applicable to all embodiments described herein, both above and below, the negative field can be applied to a conductive component, such as a screen, grid and/or tube, such as being arranged next to and/or coupled to a charged particle detector of the dual beam system 501.

The beam directing component 510 and field application component 512 can be operatively coupled to the processor 506 which can be operatively coupled to the memory 504. The bus 505 can provide for the operative coupling. The processor 506 can facilitate execution of the beam directing component 510 and field application component 512. The beam directing component 510 and field application component 512 can be stored at the memory 504.

In general, the non-limiting system 500 can employ any suitable method of communication (e.g., electronic, communicative, internet, infrared, fiber, etc.) to provide communication between the automatic locating system 502, the dual beam system 501 and/or any device associated with a user entity.

The dual beam system 501 can comprise any suitable processor and/or memory for facilitating one or more processes including, but not limited to, the generation of the negative field, alignment of the ion beam, and/or application of the ion beam. An exemplary dual beam system 700 is described below in detail. Aspects of the dual beam system 700 can apply to the dual beam system 501.

Turning next to FIG. 6, a non-limiting system 600 is illustrated that can comprise an automatic locating system 602 and dual beam system 700. Repetitive description of like elements and/or processes employed in respective embodiments is omitted for sake of brevity. Description relative to an embodiment of FIG. 5 can be applicable to an embodiment of FIG. 6. Likewise, description relative to an embodiment of FIG. 6 can be applicable to an embodiment of FIG. 5.

Generally, the automatic locating system 602 can facilitate a process for identification of an attachment region 940 of a sample support 654, such as corresponding to an edge 804 of the sample support 654, by a system associated with a focused ion beam (FIB) device 640 and an electron microscope (EM) (e.g., S/TEM 630), such as the dual beam system 700.

In one or more embodiments, the automatic locating system 602 can be at least partially comprised by the computing device 400.

In one or more embodiments, the automatic locating system 602 can at least partially comprise the dual beam system 700.

In one or more embodiments, the dual beam system 700 can at least partially comprise the automatic locating system 602.

One or more communications between one or more components of the non-limiting system 600 can be provided by wired and/or wireless means including, but not limited to, employing a cellular network, a wide area network (WAN) (e.g., the Internet), and/or a local area network (LAN). Suitable wired or wireless technologies for supporting the communications can include, without being limited to, wireless fidelity (Wi-Fi), global system for mobile communications (GSM), universal mobile telecommunications system (UMTS), worldwide interoperability for microwave access (WiMAX), enhanced general packet radio service (enhanced GPRS), third generation partnership project (3GPP) long term evolution (LTE), third generation partnership project 2 (3GPP2) ultra-mobile broadband (UMB), high speed packet access (HSPA), Zigbee and other 802.XX wireless technologies and/or legacy telecommunication technologies, BLUETOOTH®, Session Initiation Protocol (SIP), ZIGBEE®, RF4CE protocol, WirelessHART protocol, 6LoWPAN (Ipv6 over Low power Wireless Area Networks), Z-Wave, an advanced and/or adaptive network technology (ANT), an ultra-wideband (UWB) standard protocol and/or other proprietary and/or non-proprietary communication protocols.

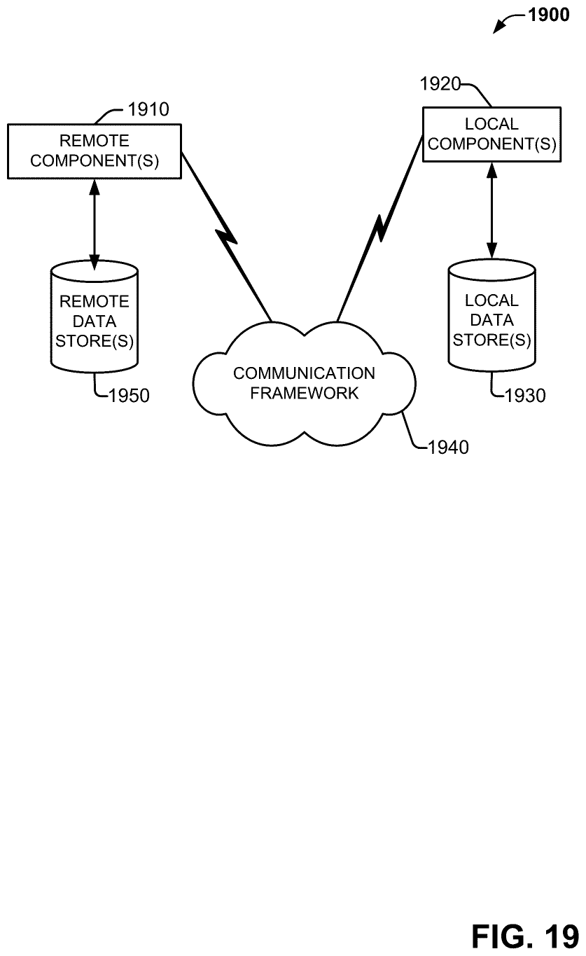

The automatic locating system 602 can be associated with, such as accessible via, a cloud computing environment, such as the cloud computing environment 1900 of FIG. 19.

The automatic locating system 602 can comprise a plurality of components. The components can comprise a memory 604, processor 606, bus 605, beam directing component 610, field application component 612, charged particle detection component 614, image generation component 616, boundary detection component 618, fitting component 620, patterning component 622 and/or execution component 624. Using these components, the automatic locating system 602 can conduct initial detection and location of a sample support 654 of a larger grid unit 650, and secondarily, can locate an attachment region 940 (FIG. 9) at the sample support 654. The attachment region 940 will be the location for attachment of a sample 1024 (FIG. 10), such as a lamella, for subsequent microscopic imaging of the sample 1024 by the dual beam system 700.

Discussion next turns to the processor 606, memory 604 and bus 605 of the automatic locating system 602. For example, in one or more embodiments, the automatic locating system 602 can comprise the processor 606 (e.g., computer processing unit, microprocessor, classical processor, quantum processor and/or like processor). In one or more embodiments, a component associated with automatic locating system 602, as described herein with or without reference to the one or more figures of the one or more embodiments, can comprise one or more computer and/or machine readable, writable and/or executable components and/or instructions that can be executed by processor 606 to provide performance of one or more processes defined by such component and/or instruction. In one or more embodiments, the processor 606 can comprise the beam directing component 610, field application component 612, charged particle detection component 614, image generation component 616, boundary detection component 618, fitting component 620, patterning component 622 and/or execution component 624.

In one or more embodiments, the automatic locating system 602 can comprise the computer-readable memory 604 that can be operably connected to the processor 606. The memory 604 can store computer-executable instructions that, upon execution by the processor 606, can cause the processor 606 and/or one or more other components of the automatic locating system 602 (e.g., beam directing component 610, field application component 612, charged particle detection component 614, image generation component 616, boundary detection component 618, fitting component 620, patterning component 622 and/or execution component 624) to perform one or more actions. In one or more embodiments, the memory 604 can store computer-executable components (e.g., beam directing component 610, field application component 612, charged particle detection component 614, image generation component 616, boundary detection component 618, fitting component 620, patterning component 622 and/or execution component 624).

The automatic locating system 602 and/or a component thereof as described herein, can be communicatively, electrically, operatively, optically and/or otherwise coupled to one another via a bus 605. Bus 605 can comprise one or more of a memory bus, memory controller, peripheral bus, external bus, local bus, quantum bus and/or another type of bus that can employ one or more bus architectures. One or more of these examples of bus 605 can be employed.

In one or more embodiments, the automatic locating system 602 can be coupled (e.g., communicatively, electrically, operatively, optically and/or like function) to one or more external systems (e.g., a non-illustrated electrical output production system, one or more output targets and/or an output target controller), sources and/or devices (e.g., classical and/or quantum computing devices, communication devices and/or like devices), such as via a network. In one or more embodiments, one or more of the components of the automatic locating system 602 and/or of the non-limiting system 600 can reside in the cloud, and/or can reside locally in a local computing environment (e.g., at a specified location).

In addition to the processor 606 and/or memory 604 described above, the automatic locating system 602 can comprise one or more computer and/or machine readable, writable and/or executable components and/or instructions that, when executed by processor 606, can provide performance of one or more operations defined by such component and/or instruction.

Discussion next turns to FIG. 7A and to description of the exemplary dual beam system 700 that can be employed as part of the non-limiting system 600. It is appreciated that in one or more embodiments, the dual beam system 700 can be employed in place of the dual beam system 501 and that description of the dual beam system 700 can also apply to the dual beam system 501.

An apparatus for performing at least a portion of one or more methods described herein is shown at FIG. 7A. FIG. 7A illustrates a typical beam system, such as a dual beam system 700, having an SEM column and a focused ion beam (FIB) column. While an example of suitable hardware is provided below, the embodiments described herein are not limited to being implemented in any particular type of hardware.

A scanning electron microscope (EM) 741, along with power supply and control unit 745, is provided with the dual beam system 700. An electron beam 743 is emitted from a cathode 752 by applying voltage between cathode 752 and an anode 754. Electron beam 743 is focused to a fine spot by means of a condensing lens 756 and an objective lens 758. Electron beam 743 is scanned two-dimensionally on the specimen by means of a deflection coil 760. Operation of condensing lens 756, objective lens 758, and deflection coil 760 is controlled by power supply and control unit 745.

The electron beam 743 can be focused onto a substrate 722, which is on movable X-Y stage 725 within lower chamber 726. When the electrons in the electron beam strike substrate 722, secondary charged particles are emitted. These secondary charged particles are detected by secondary electron detector 740 as discussed below. STEM detector 762, located beneath the TEM sample holder 724 and the stage 725, can collect electrons and/or ions that are transmitted through the sample mounted on the TEM sample holder as discussed above.

Dual beam system 700 also includes focused ion beam (FIB) system 711 which comprises an evacuated chamber having an upper neck portion 712 within which are located an ion source 714 and a focusing column 716 including extractor electrodes and an electrostatic optical system. The axis of focusing column 716 is tilted 52 degrees from the axis of the electron column. The neck portion, such as an ion column 712, can include an ion source 714, an extraction electrode 715, a focusing element 717, deflection elements 720, and/or a focused ion beam 718. Focused ion beam 718 passes from ion source 714 through focusing column 716 and between electrostatic deflection means schematically indicated at 720 toward substrate 722, which comprises, for example, a semiconductor device positioned on movable X-Y stage 725 within lower chamber 726.

Stage 725 can preferably move in a horizontal plane (X and Y axes) and vertically (Z axis). Stage 725 can also tilt approximately sixty (60) degrees and rotate about the Z axis. In some embodiments, a separate TEM sample stage (not shown) can be used. Such a TEM sample stage will also preferably be moveable in the X, Y, and Z axes. A door 761 is opened for inserting substrate 722 onto X-Y stage 725 and also for servicing an internal gas supply reservoir if one is used. The door is interlocked so that it cannot be opened if the system is under vacuum.

An ion pump 768 is employed for evacuating neck portion 712. The chamber 726 is evacuated with turbomolecular and mechanical pumping system 730 under the control of vacuum controller 732. The vacuum system provides within chamber 726 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10⁻⁵ Torr.

The high voltage power supply provides an appropriate acceleration voltage to electrodes in focusing column 716 for energizing and focusing ion beam 718. When it strikes substrate 722, material is sputtered, that is physically ejected, from the sample. Alternatively, ion beam 718 can decompose a precursor gas to deposit a material.

High voltage power supply 734 is connected to liquid metal ion source 714 as well as to appropriate electrodes in ion beam focusing column 716 for forming an approximately 1 keV to 60 keV ion beam 718 and directing the same toward a sample. Deflection controller and amplifier 736, operated in accordance with a prescribed pattern provided by pattern generator 738, is coupled to deflection plates 720 whereby ion beam 718 may be controlled manually or automatically to trace out a corresponding pattern on the upper surface of substrate 722. In some systems the deflection plates are placed before the final lens, as is well known in the art. Beam blanking electrodes (not shown) within ion beam focusing column 716 cause ion beam 718 to impact onto blanking aperture (not shown) instead of substrate 722 when a blanking controller (not shown) applies a blanking voltage to the blanking electrode.

The liquid metal ion source 714 typically provides a metal ion beam of gallium. The source typically is capable of being focused into a sub one-tenth micrometer wide beam at substrate 722 for either modifying the substrate 722 by ion milling, enhanced etch, material deposition, or for the purpose of imaging the substrate 722.

A charged particle detector 740, such as an Everhart Thornley or multi-channel plate, used for detecting secondary ion or electron emission is connected to a video circuit 742 that supplies drive signals to video monitor 744 and receiving deflection signals from a system controller 719. The location of charged particle detector 740 within lower chamber 726 can vary in different embodiments. For example, a charged particle detector 740 can be coaxial with the ion beam and include a hole for allowing the ion beam to pass. In other embodiments, secondary particles can be collected through a final lens of the SEM and then diverted off axis for collection.

A micromanipulator 747 can precisely move objects within the vacuum chamber. Micromanipulator 747 may comprise precision electric motors 748 positioned outside the vacuum chamber to provide X, Y, Z, and theta control of a portion 749 positioned within the vacuum chamber. The micromanipulator 747 can be fitted with different end effectors for manipulating small objects. In the embodiments described herein, the end effector is a thin probe 750.

A gas delivery system 746 extends into lower chamber 726 for introducing and directing a gaseous vapor toward substrate 722. For example, iodine can be delivered to enhance etching, or a metal organic compound can be delivered to deposit a metal.

System controller 719 controls the operations of the various parts of dual beam system 700. Through system controller 719, a user can cause ion beam 718 or electron beam 743 to be scanned in a desired manner through commands entered into a conventional user interface (not shown). Alternatively, system controller 719 may control dual beam system 700 in accordance with programmed instructions stored in a memory 721. In some embodiments, dual beam system 700 incorporates image recognition software to automatically identify regions of interest, and then the system can manually or automatically extract samples in accordance with the present application. For example, the system could automatically locate similar features on semiconductor wafers including multiple devices and take samples of those features on different (or the same) devices.

Turning back to FIG. 6 and now to the additional components of the automatic locating system 602 (e.g., beam directing component 610, field application component 612, charged particle detection component 614, image generation component 616, boundary detection component 618, fitting component 620, patterning component 622 and execution component 624), generally, the automatic locating system 602 can perform a set of processes that can be separated into two steps: initial location of a sample support and subsequent location of an attachment region at the sample support.

To prepare for attachment of a sample to the sample support 654, an area (e.g., an attachment region) of the sample support 654 first is to be identified and subsequently prepared. This identification also allow for accurate and secure attachment of the sample.

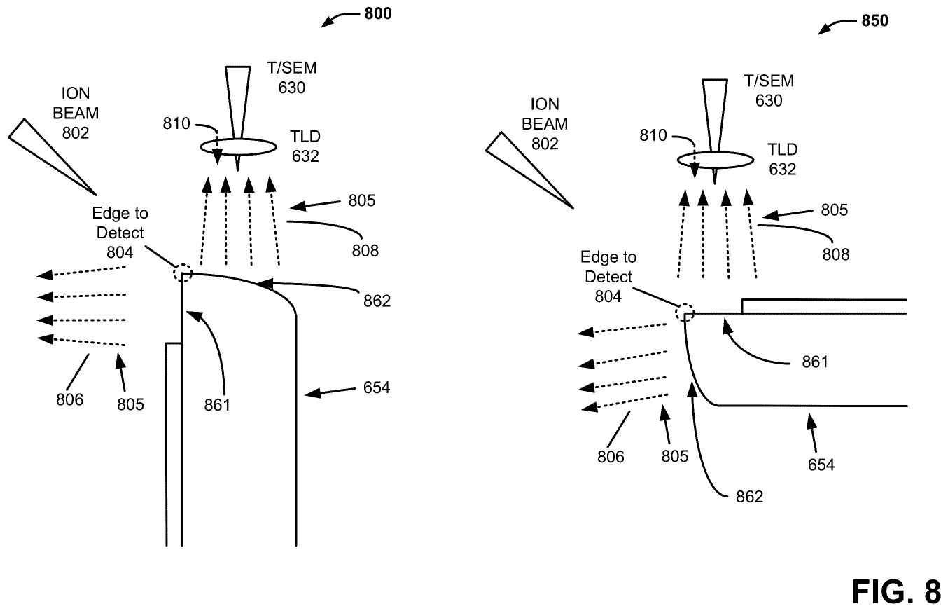

Accordingly, turning to FIG. 8, in addition to still referring to FIG. 7A, beam directing component 610 of the automatic locating system 602 can provide for cause, directing and/or otherwise instructing the FIB device 640 of the dual beam system 700 to activate an ion beam 802. Put another way, the beam directing component 610 can direct generation of the ion beam 802 from the FIB device 640 towards the sample support 654.

Generally, the sample support 654 can be one of one or more sample supports 654 of a grid system 650 comprising the one or more sample supports 654 coupled to a substrate 652.

Briefly, it is understood that any of the components described herein can be part of the dual beam system 700 and/or part of the automatic locating system 602. That is, the automatic locating system 602 can be a part of the dual beam system 700 and/or can be completely separate. Regardless, at least partial control of at least portions of the dual beam system 700 can be provided by the automatic locating system 602.

For example, relative to the beam directing component 610, it is recognized that this component can instruct and/or request activation of the ion beam 802 to the dual beam system 700, such as by sending a communication to the dual beam system 700. The communication can be obtained by a processor of the dual beam system 700, which processor in turn can direct activation of the ion beam 802. That is, the automatic locating system 602 can generally, and directly or indirectly, cause the activation of the ion beam 802.

The ion beam 802 can be directed generally towards the grid 650, upon alignment of the grid 650 relative to the FIB device 640 and relative to the EM 630. This alignment can be manual, and/or can be automatic, such as being controlled by the beam directing component 610 using a movable slide system of the dual beam system 700. The ion beam activation can comprise scanning (e.g., moving, passing over) of the ion beam 802 relative to the one or more sample supports at the grid 650, and more specifically scanning at least the sample support 654 of interest.

In connection with the activation of the ion beam 802, the field application component 612 can generally affect secondary charged particles 805, such as secondary electrons and/or secondary ions, that are generated and/or emitted from the sample support 654 due to the scanning of the material of the sample support 654 by the ion beam 802. More particularly, the field application component can cause, direct and/or instruct application of a repulsive bias, such as a negative field 810, by the dual beam system 700 during application of the ion beam 802 by the FIB device 640.

Relative to the field application component 612, it is recognized that this component can instruct and/or request activation of the negative field 810 from the dual beam system 700, such as by sending a communication to the dual beam system 700. The communication can be obtained by a processor of the dual beam system 700, which processor in turn can direct activation of the negative field 810. That is, the automatic locating system 602 can generally, and directly or indirectly, cause the activation of the negative field 810.

In one or more embodiments, the negative field 810 can be generated by the dual beam system 700, such as by the T/SEM 630, such as by a detector 632 and/or by an energy filtering component of the dual beam system 700 such as of the T/SEM 630. The detector 632 can be and/or can be comprised by the EM 741 of FIG. 7A, such as being located near a bottom of the respective EM column located in the EM chamber of the dual beam system 700.

It is appreciated that the negative field 810 can be generated by any suitable component of the dual beam system 700. It is thus further appreciated that a negative field 810 can be generated adjacent to and/or at the S/TEM 630, FIB 640 and/or other location of the dual beam system 700.

It is appreciated that a detector 632 and/or detector 740 (FIG. 7B), employed such as for detecting the secondary charged particles 805, can be disposed at any suitable location of the dual beam system 700. The dual beam system 700 can comprise any one or more detectors 632 and/or 740. It is thus further appreciated that one or more detectors 632 and/or 740 can be disposed adjacent and/or at the S/TEM 630, FIB 640 and/or other location of the dual beam system 700.

In one or more embodiments, the negative field 810 can be and/or can comprise a negative electrostatic field generated by the T/SEM 630 by applying electric potential lower than that of the sample (e.g., sample support 654) on a conductive physical component (e.g., a metal tube and/or metal screen) arranged adjacent to and/or coupled to detector 740, detector 632 or both. The sample can be grounded, allowing for electric potential equal to 0 V. Accordingly, a negative potential can be applied in the order of tens of volts, such as about −40 V.

For example, generation of the negative field 810 by the T/SEM 630 can comprise changing a sign of an applied bias (e.g., otherwise positive), where the value can determine the charge and energy of the detected particles, which, therefore can affect signal-to-noise ratio of the system, relative to the detector 632.

Put another way, directing a focused ion beam 802 toward a sample support 654 can result in the emission of secondary charged particles 805, such as secondary electrons and/or secondary ions, due to the interaction of the ions and the material of the sample support 654. The secondary charged particles 805 can then be collected by a detector 632 so that an image (e.g., initial image 902) can be generated.

To limit the detection of the desired energy of secondary charged particles 805, a conductive element adjacent to or coupled to a receiving portion of the detector 632 can be biased to repel or attract the secondary charged particles 805 desired to be detected, such as biasing with a negative voltage to repel secondary electrons while attracting secondary ions. In one or more embodiments, the level of the bias, however, may only affect charged particles of similar or lower energies, whereas charged particle of either charge of higher energies may get through or over the energy barrier generated by the biased element.

In one or more embodiments, the negative field 810 can be generally generated at an entrance or adjacent an entrance of the detector 632 to allow for the detector 632 to select and/or filter out unwanted secondary charge particles 805. For example, the negative field 810 can prevent secondary electrons, of the secondary charged particles 805, from being received at the detector 632 in favor of secondary ions, of the secondary charged particles 805. That is, the secondary ions can navigate the repulsive bias of the negative field 810, without being affected (e.g., repulsed) as are the secondary electrons. As a result, the detection of the secondary ions can provide for improved image contrast due to the charge and/or directionality of the secondary ions.

In one or more embodiments, the detector 632 can comprise a plurality of detectors. For example, another detector, other than the through the lens (TLD) detector 632 can be disposed within an EM chamber of the dual beam system 700, such as close to the SEM and FIB columns, such as the detector 740. In connection therewith, the TLD 632 could be disposed within the SEM column of the dual beam system 700.

Turning briefly to FIG. 7B, illustrated is a portion of another dual beam system 780, although it is appreciated that the illustrated portion could be part of the dual beam system 700. Illustrated at FIG. 7B is a TLD detector 632 that is disposed at and/or within the SEM column 782. Another detector 740 can be disposed within the EM chamber 783 of the dual beam system 780. Each detector 632 and 740 can comprise a respective biasing element 784, such as a screen or grid. As noted above, changing a sign of an applied bias (e.g., otherwise positive) of a biasing element 784, where the value can determine the charge and energy of the detected particles, therefore can affect signal-to-noise ratio of the system, relative to the respective detectors 632 or 740.

It will be appreciated that any one or more aspects of the dual beam system 780 can be applied to the dual beam system 700, and vice versa.

In one or more embodiments, either one, two or more than two detectors can be employed to generate an enhanced contrast image.

In one or more embodiments, one, two or more than two detectors can comprise a biasing element that comprises a screen or grid.

As an example of the above, as secondary ions of the secondary charged particles 805 can have usually higher energies (in the order of keV), the negative field 810 can have a limited effect on trajectories of the secondary ions. In this way, collection angle of the signal is effectively being increased and also consequently a detected quantity of the signal. In connection therewith, respective images from respective detectors can have only partial information and the combination of the detector images can allow for generation of an image using image processing. In one or more embodiments, more than one detector can have a negative field generating component associated therewith and/or adjacent thereto.

In one or more embodiments, one or more detectors can have a filter associated therewith to allow for filtering of secondary charged particles 805 not repulsed by the negative field 810.

In one or more embodiments, the negative field 810 can be directed towards the sample support 654 (e.g., towards a same location as the ion beam 802 is directed towards) and can emanate generally from the main column of the EM 630.

In one or more embodiments, the negative field 810 can be temporally turned on and off any suitable number of times to affect signal received by the detector 632, and thus to affect an image generated therefrom.

Based on activation of the negative field 810, which can comprise and/or cause a repulsive charge relative to at least a portion of the secondary charged particles 805, such portion of the secondary charged particles 805 can be affected. More particularly, these secondary charged particles 805 can be repelled away from the column of the T/SEM 630, and away from the through the lens detector 632 (e.g., TLD 632), which can be disposed at and/or within the SEM column.

For example, turning to FIG. 8, a first set 806 of secondary charged particles 805 originating from the sample support 654 can be repulsed away from the sample support 654 and further away from the TLD 632 by the effect of the negative field 810. This can be at least partially due to first set 806 originating from a first portion or first surface 861 of the sample support 654 that is oriented away from the TLD 632. That is, only a small portion, if any, of the secondary charged particles 805 of the first set 806 can ultimately be detected by the TLD 632 due to a combination of distance from the TLD 632 and effect of the negative field 810.

Differently, a second set 808 of secondary charged particles 805 originating from the sample support 654 can be allowed to be received by the TLD 632, and directed away from the sample from the sample support 654 due to movement of the secondary charged particles 805 (e.g., due to the application of the ion beam 802). At least partially due to originating from a second portion or second surface 862 of the sample support 654 that is closer to the EM column, a larger portion (e.g., greater quantity) of the secondary charged particles 805 of the second set 808 can be detected by the TLD 632 than of the secondary charged particles 805 of the first set 806.

Additionally, and/or alternatively, in one or more embodiments, the negative field 810 can be configured to have a power level that does not repel all secondary charged particles 805.

As a summary, in connection with the above, distance from the originating surface to the TLD 632 can be a factor in determination of quantity of first set 806 versus quantity of second set 808 received at, and therefore detected by, the TLD 632.

Further, orientation of the originating surface relative to the TLD 632 can be a factor in determination of quantity of first set 806 versus quantity of second set 808 received at, and therefore detected by, the TLD 632. That is, the first surface 861 can be oriented away from the TLD 632 and away from the second surface 862. The second surface 862 can be oriented generally towards the TLD 632. As such, the first set 806 of secondary charged particles 805 can originate from the first surface 861 oriented away from the TLD 632 and thus can be further from the TLD 632 and/or can be more greatly affected by the negative field 810 (e.g., than the second set 808). Conversely, the second set 808 of secondary charged particles can originate from the second surface 862 oriented towards the TLD 632 and thus can be closer to the TLD 632 and/or can be less greatly affected by the negative field 810 (e.g., than the first set 806).

Further, shape of the originating surface can be a factor in determination of quantity of first set 806 versus quantity of second set 808 received at, and therefore detected by, the TLD 632. That is, the first surface 861 and the second surface 862 can be different shapes. In one example, as illustrated, the first surface 861 can be planar and the second surface 862 can be curved. In another example, the first surface 861 can be curved and the second surface 862 can be planar.

As an aside, in one or more embodiments, the first surface 861 can be contiguous with the second surface 862, as illustrated at FIGS. 8 and 9. In one or more other embodiments, a first surface or second surface of relevance can be a surface of another object of the grid 650 or even a surface of a background separate from the grid 650.

Referring still referring to FIGS. 7 and 8, the charged particle detection component 614 of the automatic locating system 602 can generally direct registration of the secondary charged particles 805 that are received at and detected at the T/SEM 630 in response to the application of the ion beam 802 by the FIB device 640 to the sample support 654.

For example, relative to the charged particle detection component 614, it is recognized that this component can instruct and/or request detection of the secondary charged particles 805 by the dual beam system 700, such as by sending a communication to the dual beam system 700. The communication can be obtained by a processor of the dual beam system 700, which processor in turn can direct the activation of the TLD 632. That is, the automatic locating system 602 can generally, and directly or indirectly, cause the detection of the secondary charged particles 805.

Turning next to FIG. 9, in addition to still referring to FIGS. 7 and 8, the image generation component 616 can generally direct, cause and/or otherwise instruct generation of an image, such as the image 902, based on the receipt of and detection of the secondary charged particles 805.

In one or more embodiments, the image generation component 616 can directly generate the image 902. In one or more other embodiments, it is recognized that this component can instruct and/or request generation of the image 902 by the dual beam system 700, such as by sending a communication to the dual beam system 700. The communication can be obtained by a processor of the dual beam system 700, which processor in turn can direct generation of the image 902. That is, the automatic locating system 602 can generally, and directly or indirectly, cause the generation of the image 902.

The image 902 can be generated at any suitable screen and/or display of the non-limiting system 600, whether being a suitable screen and/or display of the automatic locating system 602 or of the dual beam system 700.

In particular, the image 902 can be generated, whether directly or indirectly by the image generation component 616, based on receipt of the second set 808 of secondary charged particles 805 at the detector 632 and lack of receipt of the first set 806 of secondary charged particles 805 at the detector 632. Put another way, the image 902 can be generated, whether directly or indirectly by the image generation component 616, based on receipt of a larger second quantity of secondary charged particles 805 of the second set 808 of secondary charged particles 805 at the detector 632 than a smaller first quantity of secondary charged particles 805 of the first set 806 of secondary charged particles 805 at the detector 632.

It will be appreciated that the general contrast between the regions 931 and 932 can be at least partially controlled by settings relative to the ion beam 802 and negative field 810. That is, an increase in ion quantity of the ion beam 802 (e.g., increase in power of the ion beam 802) can cause additional secondary charged particles 805 of both sets 806 and 808. Additionally, and/or alternatively, an increase in power of the negative field 810 can cause repulsion of additional secondary charged particles 805 away from the TLD 632 (e.g., in addition to those caused by a lesser power level of the negative field 810). For example, on order of 1e11 ions can be generated in the case of a 1.2 nA beam, with respect to an image comprising 3072×2048 pixels, with a dwell time of 1e-6s per pixel, without being limited thereto. Other combinations can be suitable.

As a result, as illustrated at image 902, a first region 931, corresponding to the first surface 861 of the sample support 654, has a lesser signal than a second region 932, corresponding to the second surface 862 of the sample support 654, which has a greater signal. As used herein, “signal” can comprise image pixel information for generating an image (e.g., image 902 of FIG. 9). The greater signal can be directly due to receipt of a greater second quantity of secondary charged particles 805 of the second set 808 of secondary charged particles 805. As a result, the first region 931 and second region 932 can be highly contrasted relative to one another, which can allow for easy automatic distinguishing between the regions 931 and 932 by image detection components and functions of the non-limiting system 600. Accordingly, as compared to existing frameworks, the non-limiting system 600 can provide for easy automatic distinguishing of boundaries 934, 936 between different surfaces of the aspects being imaged. This distinguishing and imaging can be a direct result of the application of the negative field 810 and can reduce and/or altogether eliminate various manual aspects of existing frameworks. Moreover, this distinguishing and imaging can allow for more accurate (e.g., a narrower surface area) locating of an attachment region 940, which accuracy can comprise locating of a smaller and more precise attachment region 940 than is possible with existing frameworks.

Discussion next turns to additional modification steps that can be caused, directed and/or otherwise instructed by the image generation component 616 and/or by the processor of the dual beam system 700.

As illustrated at image 904, denoising and thresholding can be performed on the image 902. For example, different algorithms can be employed for thresholding where an image is grayscale, and each pixel can range from 0 to 255. For example, a threshold value T can be selected, with every pixel having a value below T being set to 1 and every pixel having a value above T being set to 255.

As illustrated at image 906, image dilation and/or image erosion processes can be performed on the image 904 that results from the denoising and thresholding.

For example, dilatation can work on black-and-white images by inflating the black regions in the image. Dilation expands the boundaries of the black regions through the addition of black pixels to the outer edges. The extent of expansion can be determined by a structuring element, which is a small pattern or mask used to guide the dilatation process. Dilatation can be used to connect nearby objects, fill gaps, and make objects larger or thicker.

Erosion operates by shrinking the black regions in the image through removing pixels from the boundary of the black regions based on the same structuring element used in dilatation. Erosion can be useful for removing small noise or fine details in an image and making objects smaller or thinner. These operations are often used together in a process called morphological operations, which can be employed for various image processing tasks, like noise reduction, edge detection, and feature extraction.

Turning now to the identification of the boundaries 934, 936, the boundary detection component 618 can generally direct, cause and/or otherwise instruct identification of a boundary between the first region 931 and the second region 932, such as the boundary 934. In one or more cases, as illustrated in the figures, the boundary 934 can correspond to an edge of the sample support 654, such as an edge 804. As illustrated at FIG. 8, the edge 804 is a physical delineation between the first surface 861 and the second surface 862. Identification of an edge of the sample support 654 can allow for use of a physical delineation or marker (e.g., the edge) for easier and/or more efficient subsequent alignment and attachment of a sample (e.g., lamella).

Alternatively, in one or more other embodiments, it is appreciated that a boundary identified by the boundary detection component 618 can be a virtual boundary, such as on an image, such as between a physical feature (e.g., surface, edge, etc.) of the sample support and a background being imaged (e.g., of the grid 950 behind the sample support and/or of the surrounding environment).

Accordingly, as illustrated at image 906, edge detection can be performed, allowing for particular identification of the boundary 934 between the first region 931 and the second region 932. A thickness of the boundary 934 can be selected by the boundary detection component 618 and/or by the processor of the dual beam system 700, for example, without being limited thereto.

Next, resulting from the image 906, the image detection functions of the non-limiting system 600 can identify only the boundary 934, negating the boundary 936, and generating the edge image 910 with the boundary 934.

Subsequently, the fitting component 620 can generally direct, cause and/or otherwise instruct fitting of a suitable shape, such as a curve, such as a parabola, to the identified boundary 934. As illustrated at the image 912 of FIG. 9, a parabola 938 can be generally fit to the boundary 934, and thus corresponding to the edge 804 of the sample support 654.

Next, the patterning component 622 can generally direct, cause and/or otherwise instruct application of a virtual pattern (e.g., pattern 942) overlaying an identified portion (e.g., the attachment region 940) of the image (e.g., image 912) of the sample support 654. As a result, the identified portion (e.g., the attachment region 940) corresponds to, and can overlap, at least a portion of the identified boundary 934 between the first region 931 and the second region 932.

Referring now again to FIG. 8, it is noted that orientation of the dual beam 700, and thus orientation of a column of the FIB device 640 and a column of the EM 630 can be adjusted, such as to provide imaging as illustrated at setup 850 of FIG. 8. In one or more embodiments, this orientation can be conducted in addition to or omitted relative to orientation of a stage of the support grid supporting the sample support 654. That is, different from the setup 800 as corresponds to FIG. 9, the setup 850 can result in the first surface 861 corresponding to the higher signal region and the second surface 862 corresponding to the lower signal region. That is, orientation of the sample support 654 relative to the dual beam system 700 and/or orientation of the dual beam system 700 relative to the sample support 654 can be adjusted for differing images. Indeed, the processes described herein can be applicable and function well with either setup 800 or 850 and/or with other setups as may be suitable.

Referring now to FIG. 10, upon, before and/or at least partially in parallel with identification of the attachment region 940, the processes of FIG. 10 can be performed separately from the non-limiting system 600 and/or using the dual beam system 700. That is, region of interest (ROI) identification 1002 can be performed to identify a portion 1020 of a sample to be imaged by being attached to the attachment region 940 of the sample support 654. At step 1004, a smaller portion 1024 (e.g., lamella 1024) of the sample portion 1020 can be cut out of the overall sample by forming a trench 1022, such as using an ion beam 802 of the FIB device 640. At step 1006, a sample retrieval tool 1026 can be employed to attach to and extract (e.g., lift-out) the lamella 1024 from the trench 1022 of the overall sample body. The lamella 1024 can then be attached to the attachment region 940 using the sample retrieval tool 1026.

For example, referring to image 1100 of FIG. 11, the attachment region 940 can be trenched based on the patterning directed by the patterning component 622. The trenching can be performed by the ion beam 802 of the FIB device 640. Thereafter, the lamella 1024 can be directed to the trenched attachment region 940 by the sample retrieval tool 1026. The lamella 1024 can be welded to the attachment region 940, such as using the ion beam 802 of the FIB device 640. As illustrated at image 1150, the sample retrieval tool 1026 can be cut free from the attached lamella 1024, such as using the ion beam 802 of the FIB device 640.

As illustrated, the fiducial 1120 can be employed for tracking position of the sample support 654 and/or placement of the sample 1024.

Turning back briefly to FIG. 10, after the final attachment of the lamella 1024 and freeing of the sample retrieval tool 1026, the lamella 1024 can be further processed. For example, at step 1008, the lamella can be thinned and/or polished, resulting in a thinned and/or polished section 1028 of the lamella 1024. This section 1028 can be subsequently imaged using the S/TEM 630, at step 1010, resulting in a high resolution image 1012. The thinning, polishing and/or imaging can all be more efficiently performed due to a more secure and more precise attachment of the lamella 1024 to the sample support 654, in turn due to the use of the non-limiting system 600, and including the imaging generated as a result of application of the negative field 810, among the other processes described above (e.g., without being limited to only application of the negative field 810).

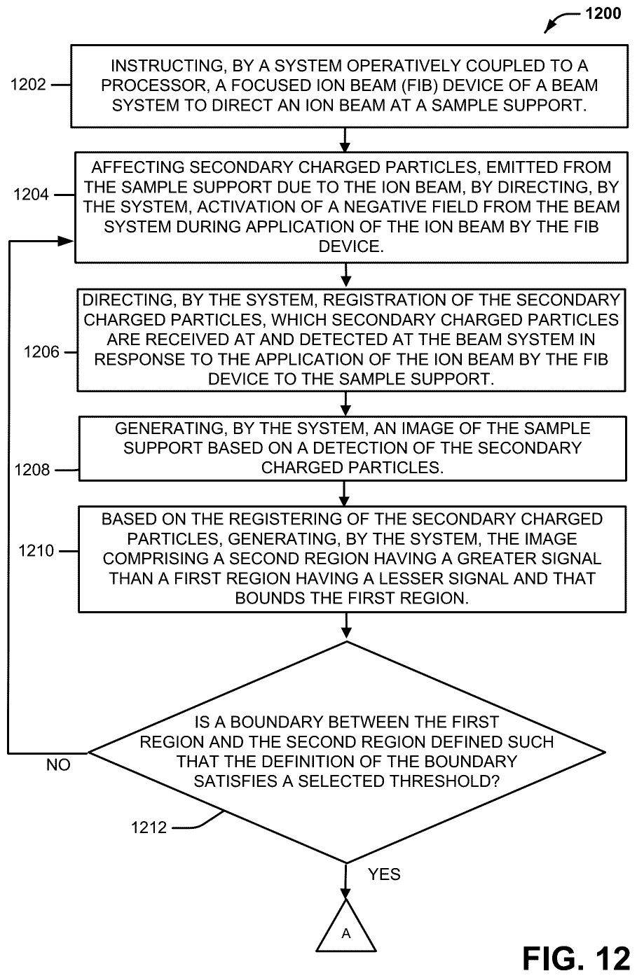

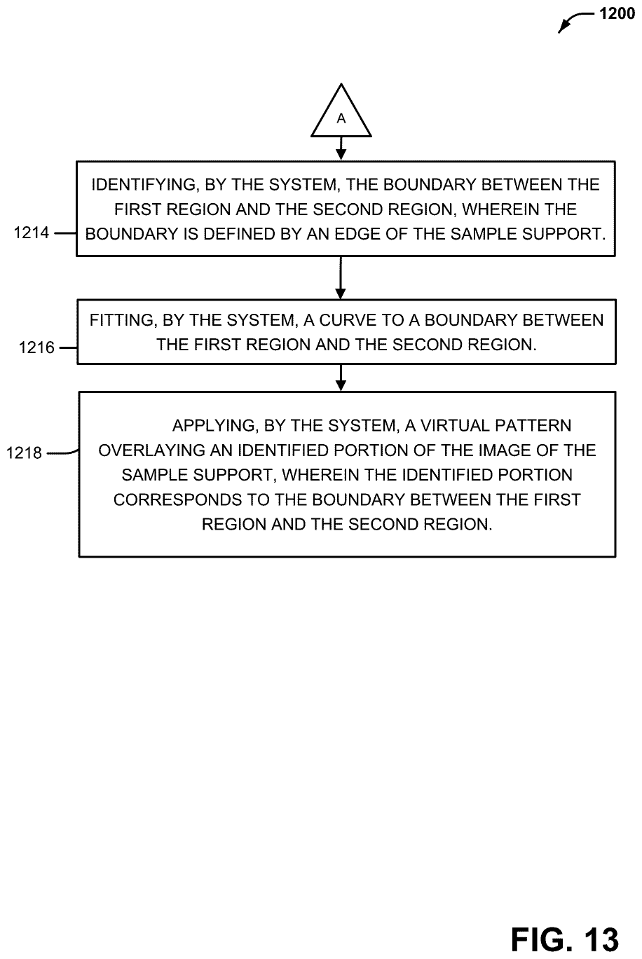

As a summary of the above-described components and functions thereof, referring next to FIGS. 12 and 13, illustrated is a flow diagram of an example, non-limiting method 1200 that can facilitate a process for identification of an attachment region of a sample support, in accordance with one or more embodiments described herein, such as the non-limiting system 600 of FIG. 6. While the non-limiting method 1200 is described relative to the non-limiting system 600 of FIG. 6, the non-limiting method 1200 can be applicable also to other systems described herein, such as the non-limiting system 500 of FIG. 5. Repetitive description of like elements and/or processes employed in respective embodiments is omitted for sake of brevity.

At 1202, the non-limiting method 1200 can comprise instructing, by a system operatively coupled to a processor (e.g., beam directing component 610 coupled to processor 506), a focused ion beam (FIB) device (e.g., FIB device 640) of a beam system (e.g., dual beam system 700) to direct an ion beam (e.g., ion beam 802) at a sample support (e.g., sample support 654).

At 1204, the non-limiting method 1200 can comprise affecting secondary charged particles (e.g., secondary charged particles 805), emitted from the sample support due to the ion beam, by directing, by the system (e.g., field application component 612), activation of a negative field (e.g., negative field 810) from the beam system during application of the ion beam by the FIB device.

In one or more embodiments, an electron microscope (EM) (e.g., T/SEM 630), of the beam system, and the FIB device can be communicatively coupled to the processor, wherein the EM comprises a detector (e.g., detector 632) that detects the secondary charged particles (e.g., secondary charged particles 805), wherein the detector is coupled to or disposed adjacent to a conductive component of the beam system, and wherein the negative field is applied to the conductive component.

At 1206, the non-limiting method 1200 can comprise, directing, by the system (e.g., charged particle detection component 614), registration of the secondary charged particles, which secondary charged particles are received at and detected at the beam system in response to the application of the ion beam by the FIB device to the sample support.

At 1208, the non-limiting method 1200 can comprise generating, by the system (e.g., image generation component 616), an image (e.g., image 902) of the sample support based on a detection of the secondary charged particles.

At 1210, the non-limiting method 1200 can comprise, based on the registering of the secondary charged particles, generating, by the system (e.g., image generation component 616), the image comprising a second region (e.g., second region 932) having a greater signal than a first region (e.g., first region 931) having a lesser signal and that bounds the first region.

At 1212, the non-limiting method 1200 can comprise determining, by the system (e.g., image generation component 616), whether or not a boundary (e.g., boundary 934) between the first region and the second region is defined such that the definition of the boundary satisfies a selected threshold. If yes, the non-limiting method 1200 can proceed to step 1214. If not, the non-limiting method 1200 can proceed back to step 1204 and again implement the negative field during application of the ion beam by the FIB device, but with an adjusted negative field (e.g., adjusting power, frequency, time duration, etc.).

At 1214, the non-limiting method 1200 can comprise identifying, by the system (e.g., boundary detection component 618), the boundary between the first region and the second region, wherein the boundary (e.g., boundary 934) is defined by an edge (e.g., edge 804) of the sample support.

At 1216, the non-limiting method 1200 can comprise fitting, by the system (e.g., fitting component 620), a curve (e.g., curve 938) to a boundary between the first region and the second region.

At 1218, the non-limiting method 1200 can comprise applying, by the system (e.g., patterning component 622), a virtual pattern overlaying an identified portion of the image of the sample support, wherein the identified portion corresponds to the boundary (e.g., boundary 934) between the first region and the second region.

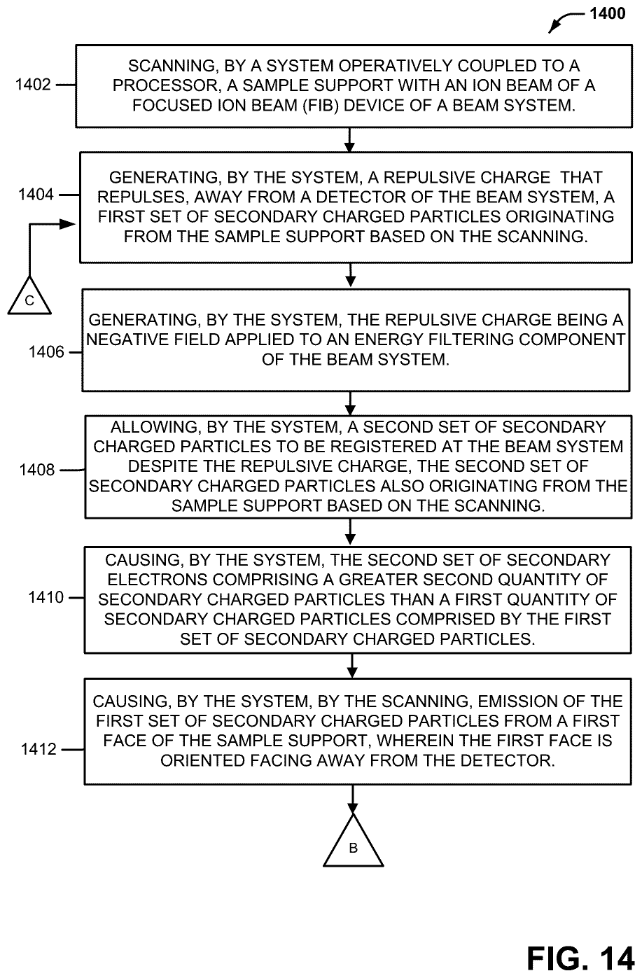

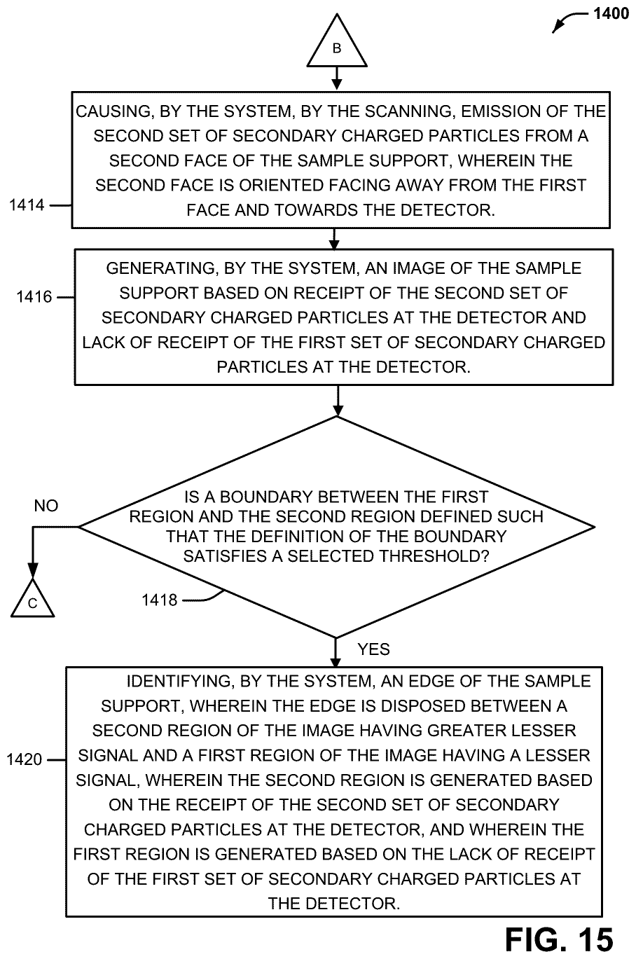

As another summary of the above-described components and functions thereof, referring next to FIGS. 14 and 15, illustrated is a flow diagram of an example, non-limiting method 1400 that can facilitate a process for identification of an attachment region of a sample support, in accordance with one or more embodiments described herein, such as the non-limiting system 600 of FIG. 6. While the non-limiting method 1400 is described relative to the non-limiting system 600 of FIG. 6, the non-limiting method 1400 can be applicable also to other systems described herein, such as the non-limiting system 500 of FIG. 5. Repetitive description of like elements and/or processes employed in respective embodiments is omitted for sake of brevity.

At 1402, the non-limiting method 1400 can comprise scanning, by a system operatively coupled to a processor (e.g., beam directing component 610 directing FIB device 640 coupled to processor 606) a sample support (e.g., sample support 654) with an ion beam (e.g., ion beam 802) of a focused ion beam (FIB) device of a beam system (e.g., dual beam system 700).

At 1404, the non-limiting method 1400 can comprise generating, by the system (e.g., field application component 612 directing T/SEM 630), a repulsive charge (e.g., resulting from a negative field 810) that repulses, away from a detector (e.g., detector 632) of the beam system, a first set of secondary charged particles (e.g., first set 806 of secondary charged particles 805) originating from the sample support based on the scanning.

At 1406, the non-limiting method 1400 can comprise generating, by the system (e.g., field application component 612 directing T/SEM 630), the repulsive charge being a negative field applied to an energy filtering component (e.g., energy filtering component 634) of the beam system.

At 1408, the non-limiting method 1400 can comprise allowing, by the system (e.g., T/SEM 630), a second set of secondary charged particles (e.g., second set 808 of secondary charged particles 805) to be registered at the beam system despite the repulsive charge, the second set of secondary charged particles also originating from the sample support based on the scanning.

At 1410, the non-limiting method 1400 can comprise causing, by the system (e.g., field application component 612 directing T/SEM 630), the second set of secondary charged particles comprising a greater second quantity of secondary charged particles than a first quantity of secondary charged particles comprised by the first set of secondary charged particles.

At 1412, the non-limiting method 1400 can comprise causing, by the system (e.g., beam directing component 610 directing FIB device 640), by the scanning, emission of the first set of secondary charged particles from a first face of the sample support, wherein the first face is oriented facing away from the detector.

At 1414, the non-limiting method 1400 can comprise causing, by the system (e.g., beam directing component 610 directing FIB device 640), by the scanning, emission of the second set of secondary charged particles from a second face of the sample support, wherein the second face is oriented facing away from the first face and towards the detector.

In one or more embodiments, the first face is planar, and the second face is curved, and the first face is contiguous with the second face. In one or more other embodiments, the first face is curved, and the second face is planar.

At 1416, the non-limiting method 1400 can comprise generating, by the system (e.g., image generation component 616), an image (e.g., image 902) of the sample support based on receipt of the second set of secondary charged particles at the detector and lack of receipt of the first set of secondary charged particles at the detector.

At 1418, the non-limiting method 1400 can comprise determining, by the system (e.g., image generation component 616), whether or not a boundary (e.g., boundary 934) between the first region and the second region is defined such that the definition of the boundary satisfies a selected threshold. If yes, the non-limiting method 1400 can proceed to step 1420. If not, the non-limiting method 1400 can proceed back to step 1404 and again implement the negative field during application of the ion beam by the FIB device, but with an adjusted negative field (e.g., adjusting power, frequency, time duration, etc.).

At 1420, the non-limiting method 1400 can comprise identifying, by the system (e.g., boundary detection component 618), an edge of the sample support, wherein the edge is disposed between a second region (e.g., second region 932) of the image having greater lesser signal and a first region (e.g., first region 931) of the image having a lesser signal, wherein the second region is generated based on the receipt of the second set of secondary charged particles at the detector, and wherein the first region is generated based on the lack of receipt of the first set of secondary charged particles at the detector.

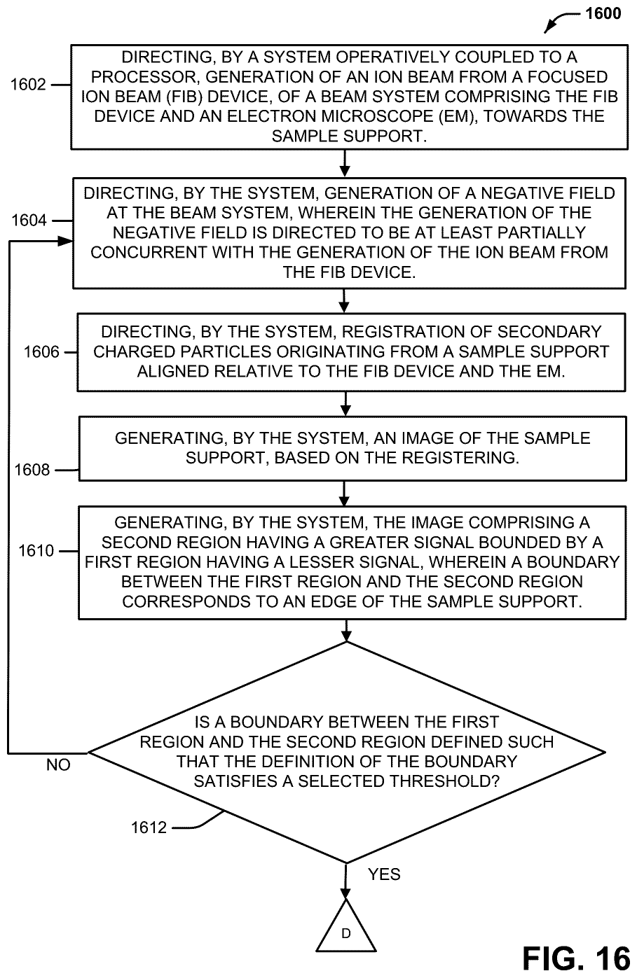

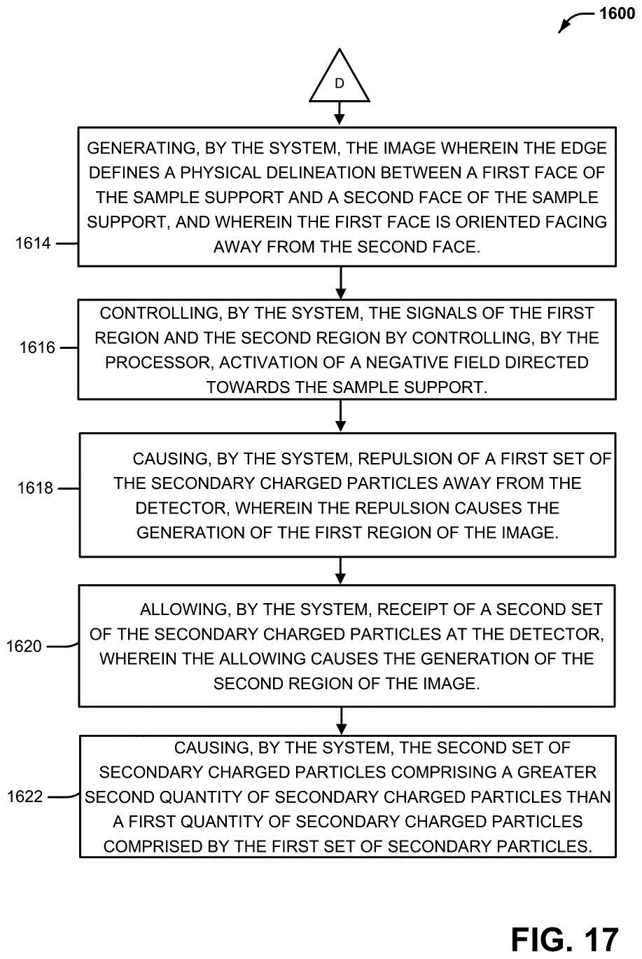

As still another summary of the above-described components and functions thereof, referring next to FIGS. 16 and 17, illustrated is a flow diagram of an example, non-limiting method 1600 that can facilitate a process for identification of an attachment region of a sample support, in accordance with one or more embodiments described herein, such as the non-limiting system 600 of FIG. 6. While the non-limiting method 1600 is described relative to the non-limiting system 600 of FIG. 6, the non-limiting method 1600 can be applicable also to other systems described herein, such as the non-limiting system 500 of FIG. 5. Repetitive description of like elements and/or processes employed in respective embodiments is omitted for sake of brevity.

At 1602, the non-limiting method 1600 can comprise directing, by a system operatively coupled to a processor (e.g., beam directing component 610), generation of an ion beam (e.g., ion beam 802) from a focused ion beam (FIB) device (e.g., FIB device 640), of a beam system (e.g., dual beam system 700) comprising the FIB device and an electron microscope (EM) (e.g., T/SEM 630), towards a sample support e.g., sample support (e.g., sample support 654).

At 1604, the non-limiting method 1600 can comprise directing, by the system (e.g., field application component 612), generation of a negative field (e.g., negative field 810) at the beam system, wherein the generation of the negative field is directed to be at least partially concurrent with the generation of the ion beam from the FIB device.

At 1606, the non-limiting method 1600 can comprise directing, by the system (e.g., charged particle detection component 614), registration of secondary charged particles (e.g., secondary charged particles 805) originating from the sample support aligned relative to the FIB device and the EM.

At 1608, the non-limiting method 1600 can comprise generating, by the system (e.g., image generation component 616), an image (e.g., image 902) of the sample support, based on the registering.

At 1610, the non-limiting method 1600 can comprise generating, by the system (e.g., image generation component 616), the image comprising a second region (e.g., second region 932) having a greater signal bounded by a first region (e.g., first region 931) having a lesser signal, wherein a boundary (e.g., boundary 934) between the first region and the second region corresponds to an edge (e.g., edge 804) of the sample support.

At 1612, the non-limiting method 1600 can comprise determining, by the system (e.g., image generation component 616), whether or not the boundary (e.g., boundary 934) between the first region and the second region is defined such that the definition of the boundary satisfies a selected threshold. If yes, the non-limiting method 1200 can proceed to step 1614. If no, the non-limiting method 1600 can proceed back to step 1604 and again implement the negative field during application of the ion beam by the FIB device, but with an adjusted negative field (e.g., adjusting power, frequency, time duration, etc.).

At 1614, the non-limiting method 1600 can comprise generating, by the system (e.g., image generation component 616), the image wherein the edge defines a physical delineation between a first face (e.g., first face 821) of the sample support and a second face (e.g., second face 822) of the sample support, and wherein the first face is oriented facing away from the second face.

At 1616, the non-limiting method 1600 can comprise controlling, by the system (e.g., field application component 612), the signals of the first region and the second region by controlling, by the processor, activation of a negative field directed towards the sample support.

At 1618, the non-limiting method 1600 can comprise causing, by the system (e.g., field application component 612), repulsion of a first set (e.g., first set 806) of the secondary charged particles away from a detector (e.g., detector 632), wherein the repulsion causes the generation of the first region of the image.

At 1620, the non-limiting method 1600 can comprise allowing, by the system (e.g., field application component 612), receipt of a second set (e.g., second set 808) of the secondary charged particles at the detector, wherein the allowing causes the generation of the second region of the image.

At 1622, the non-limiting method 1600 can comprise causing, by the system (e.g., field application component 612), the second set of secondary charged particles comprising a greater second quantity of secondary charged particles than a first quantity of secondary charged particles comprised by the first set of secondary charged particles.

### Additional Summary

For simplicity of explanation, the computer-implemented and non-computer-implemented methodologies provided herein are depicted and/or described as a series of acts. It is to be understood that the subject innovation is not limited by the acts illustrated and/or by the order of acts, for example acts can occur in one or more orders and/or concurrently, and with other acts not presented and described herein. Furthermore, not all illustrated acts can be utilized to implement the computer-implemented and non-computer-implemented methodologies in accordance with the described subject matter. In addition, the computer-implemented and non-computer-implemented methodologies could alternatively be represented as a series of interrelated states via a state diagram or events. Additionally, the computer-implemented methodologies described hereinafter and throughout this specification are capable of being stored on an article of manufacture for transporting and transferring the computer-implemented methodologies to computers. The term article of manufacture, as used herein, is intended to encompass a computer program accessible from any computer-readable device or storage media.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

In summary, one or more systems, computer program products and/or computer-implemented methods provided herein relate to sample support imaging and sample location identification at a sample support to be used for microscopy imaging. A system can comprise a memory that stores, and a processor that executes, computer executable components. The computer executable components can comprise a beam directing component that instructs a focused ion beam (FIB) device of a beam system to direct an ion beam at a sample support, and a field application component that affects secondary charged particles, emitted from the sample support due to the ion beam, by directing activation of a negative field from the beam system during application of the ion beam by the FIB device.

The one or more embodiments disclosed herein can achieve improved performance relative to existing approaches. For example, based on application of a negative field during imaging by a dual beam system (applying an ion beam to a sample and detecting generated secondary charged particles), an image having greater area of greater contrasting signal can be generated. This can allow for more efficient and more accurate identification of an edge of a sample support being imaged by the dual beam system, as compared to existing techniques. In turn, this can allow for more accurate placement of a sample on and/or at the sample support, as compared to existing techniques.

The placement of the sample can be made more efficient and accurate because an attachment region on the sample support can be more accurately identified, in view of the one or more embodiments described herein. Further, a reduced quantity and/or smaller area of sample substrate can be removed from the identified region due to the more efficient and accurate identification of the attachment region on the sample support, as compared to existing techniques.

In one or more embodiments described herein, identification of an attachment region of a sample support can be made automatic to thereby reduce and/or eliminate manual identification of the attachment region. In turn, this can reduce location identification error, increase location identification accuracy and/or time to successful location identification than can be provided by existing techniques.

Further, the embodiments described herein can be adapted to work with sample supports have various different shaped surfaces, a sample support in combination with a background and/or non-sample support applications such as, but not limited to, imaging of a sample. Additionally, and/or alternatively, the embodiments described herein can be adapted to identify an edge or another feature, such as a curve, apex, peak, point, divot, trench and/or the like.

Indeed, in view of the one or more embodiments described herein, a practical application of the one or more systems, computer-implemented methods and/or computer program products described herein can be ability to automatically identify an edge or other feature of an object being imaged by a dual beam system (e.g., comprising a FIB device and an EM). This identification can be performed to narrow down the attachment region to a more precise region, as compared to existing techniques for attachment region identification. This identification also can be performed efficiently and accurately without manual input, thus reducing the time to identification.

Further due to the accurate feature identification that can be performed by the one or more embodiments described herein, a sample can be attached to a sample support, having been imaged and comprising the attachment region, in a more precise attachment, such as being located more precisely relative to the attachment region and/or more precisely being angled (e.g., attachment angle) relative to the attachment region.

These are useful and practical applications of computers, thus providing for subsequent enhanced (e.g., improved and/or optimized) material preparation and analysis. That is, a sample (such as a lamella), attached to an attachment region of a sample support, can be thinned, polished and/or imaged more accurately due to a better identification by respective computer systems of the attachment region, as a result of the initial attachment region automatic identification. Overall, such computerized tools can constitute a concrete and tangible technical improvement in the fields of material analysis, and more particularly in material analysis using a dual beam system.

Furthermore, one or more embodiments described herein can be employed in a real-world system based on the disclosed teachings. For example, as noted above, the increased contrast in signal of an increased area of object being imaged can directly result in more accurate physical placement of a physical sample at a physical sample support (comprising the attachment region identified), as compared to existing techniques. This real-world result can be made possible due to the ability to detect secondary charged particles having been acted upon by an applied negative field, thus providing for high accuracy in computer-aided recognition of the one or more features of the object being images using the applied negative field. The embodiments disclosed herein thus can provide improvements to scientific instrument technology (e.g., improvements in the computer technology supporting such scientific instruments, among other improvements).

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

One or more embodiments described herein can be, in one or more embodiments, inherently and/or inextricably tied to computer technology and cannot be implemented outside of a computing environment. For example, one or more processes performed by one or more embodiments described herein can more efficiently, and even more feasibly, provide program and/or program instruction execution, such as relative to automatic attachment region identification using a dual beam system, as compared to existing systems and/or techniques using a FIB device, EM and/or dual beam system. Systems, computer-implemented methods and/or computer program products providing performance of these processes are of great utility in the fields of material analysis, such as in material analysis using a dual beam system and cannot be equally practicably implemented in a sensible way outside of a computing environment.

One or more embodiments described herein can employ hardware and/or software to solve problems that are highly technical, that are not abstract, and that cannot be performed as a set of mental acts by a human. For example, a human, or even thousands of humans, cannot efficiently, accurately and/or effectively automatically identify a feature, such as an edge, such as a curved edge, of a sample support for subsequent placement of a sample at the sample support relative to the feature, as the one or more embodiments described herein can provide this process. Moreover, neither can the human mind nor a human with pen and paper conduct one or more of these processes, as conducted by one or more embodiments described herein.

In one or more embodiments, one or more of the processes described herein can be performed by one or more specialized computers (e.g., a specialized processing unit, a specialized classical computer, a specialized quantum computer, a specialized hybrid classical/quantum system and/or another type of specialized computer) to execute defined tasks related to the one or more technologies describe above. One or more embodiments described herein and/or components thereof can be employed to solve new problems that arise through advancements in technologies mentioned above, employment of quantum computing systems, cloud computing systems, computer architecture and/or another technology.

One or more embodiments described herein can be fully operational towards performing one or more other functions (e.g., fully powered on, fully executed and/or another function) while also performing one or more of the one or more operations described herein.

To provide additional summary, a listing of embodiments and features thereof is next provided.

A system, comprising: a memory that stores computer executable components; and a processor that executes the computer executable components stored in the memory, wherein the computer executable components comprise: a beam directing component that instructs a focused ion beam (FIB) device to direct an ion beam at a sample support; and a field application component that affects secondary charged particles, emitted from the sample support due to the ion beam, by directing activation of a negative field from an electron microscope (EM) during application of the ion beam by the FIB device.

The system of the preceding paragraph, further comprising: a charged particle detection component that directs registration of the secondary charged particles, which secondary charged particles are received at and detected at the EM in response to the application of the ion beam by the FIB device to the sample support.

The system of any preceding paragraph, further comprising: an image generation component that generates an image of the sample support based on a detection of the secondary charged particles, wherein, based on the registering of the secondary charged particles, the image comprises a second region having a greater signal than a first region having a lesser signal and that bounds the second region.

The system of any preceding paragraph, further comprising: a boundary detection component that identifies a boundary between the first region and the second region, wherein the boundary is defined by an edge of the sample support.

The system of any preceding paragraph, further comprising: a fitting component that fits a curve to a boundary between the first region and the second region.

The system of any preceding paragraph, further comprising: a patterning component that applies a virtual pattern overlaying an identified portion of the image of the sample support, wherein the identified portion corresponds to a boundary between the first region and the second region.

The system of any preceding paragraph, further comprising: the EM and the FIB device communicatively coupled to the processor, wherein the EM comprises a detector that detects the secondary charged particles, wherein the detector is coupled to or disposed adjacent to a conductive component of the beam system, and wherein the negative field is applied to the conductive component.

A computer-implemented method, comprising: scanning, by a system operatively coupled to a processor, a sample support with an ion beam of a focused ion beam (FIB) device; generating, by the system, a repulsive charge that repulses, away from a detector of an electron microscope (EM), a first set of secondary charged particles originating from the sample support based on the scanning; and allowing, by the system, a second set of secondary charged particles to be registered at the EM despite the repulsive charge, the second set of secondary charged particles also originating from the sample support based on the scanning.

The computer-implemented method of the preceding paragraph, further comprising: generating, by the system, the repulsive charge being a negative field applied to an energy filtering component of the EM.

The computer-implemented method of any preceding paragraph, wherein the second set of secondary charged particles comprises a greater second quantity of secondary charged particles than a first quantity of secondary charged particles comprised by the first set of secondary charged particles.

The computer-implemented method of any preceding paragraph, further comprising: causing, by the scanning, emission of the first set of secondary charged particles from a first face of the sample support, wherein the first face is oriented facing away from a detector; and causing, by the scanning, emission of the second set of secondary charged particles from a second face of the sample support, wherein the second face is oriented facing away from the first face and towards the detector.

The computer-implemented method of any preceding paragraph, wherein first face is planar and the second face is curved, and wherein the first face is contiguous with the second face.

The computer-implemented method of any preceding paragraph, further comprising: generating, by the system, an image of the sample support based on receipt of the second set of secondary charged particles at the detector and lack of receipt of the first set of secondary charged particles at the detector.

The computer-implemented method of any preceding paragraph, further comprising: identifying, by the system, an edge of the sample support, wherein the edge is disposed between a second region of the image having greater lesser signal and a first region of the image having a lesser signal, wherein the second region is generated based on the receipt of the second set of secondary charged particles at the detector, and wherein the first region is generated based on the lack of receipt of the first set of secondary charged particles at the detector.

A computer program product facilitating a process for identification of an edge of a sample support by a system associated with a focused ion beam (FIB) device and an electron microscope (EM), the computer program product comprising a computer readable storage medium having program instructions embodied therewith, and the program instructions executable by a processor to cause the processor to: register, by the processor, secondary charged particles originating from a sample support aligned relative to the FIB device and the EM; and generate, by the processor, an image of the sample support, based on the registering, wherein the image comprises a second region having a greater signal bounded by a first region having a lesser signal, and wherein a boundary between the first region and the second region corresponds to an edge of the sample support.

The computer program product of the preceding paragraph, wherein the program instructions are further executable by the processor to cause the processor to: control, by the processor, the signals of the first region and the second region by controlling, by the processor, activation of a negative field directed towards the sample support.

The computer program product of any preceding paragraph, wherein the program instructions are further executable by the processor to cause the processor to: cause, by the processor, repulsion of a first set of the secondary charged particles away from a detector, wherein the repulsion causes the generation of the first region of the image; and allow, by the processor, receipt of a second set of the secondary charged particles at the detector, wherein the allowing causes the generation of the second region of the image.

The computer program product of any preceding paragraph, wherein the second set of secondary charged particles comprises a greater second quantity of secondary charged particles than a first quantity of secondary charged particles comprised by the first set of secondary charged particles.

The computer program product of any preceding paragraph, wherein the program instructions are further executable by the processor to cause the processor to: direct, by the processor, generation of an ion beam from the FIB device towards the sample support; and direct, by the processor, generation of a negative field at a beam system comprising the EM and the FIB device, wherein the generation of the negative field is directed to be at least partially concurrent with the generation of the ion beam from the FIB device.

The computer program product of any preceding paragraph, wherein the edge defines a physical delineation between a first face of the sample support and a second face of the sample support, and wherein the first face is oriented facing away from the second face.

### Scientific Instrument System Description

Turning next to FIG. 18, a detailed description is provided of additional context for the one or more embodiments described herein at FIGS. 1-12. One or more computing devices implementing any of the scientific instrument modules or methods disclosed herein can be part of a scientific instrument system. FIG. 18 illustrates a block diagram of an example scientific instrument system 1800 in which one or more of the scientific instrument methods or other methods disclosed herein can be performed, in accordance with various embodiments described herein. The scientific instrument modules and methods disclosed herein (e.g., the scientific instrument module 100 of FIG. 1 and the method 200 of FIG. 2) can be implemented by one or more of the scientific instrument 1810, the user local computing device 1820, the service local computing device 1830, and/or the remote computing device 1840 of the scientific instrument system 1800.

Any of the scientific instrument 1810, the user local computing device 1820, the service local computing device 1830, and/or the remote computing device 1840 can include any of the embodiments of the computing device 400 discussed herein with reference to FIG. 4, and any of the scientific instrument 1810, the user local computing device 1820, the service local computing device 1830, and/or the remote computing device 1840 can take the form of any appropriate one or more of the embodiments of the computing device 400 discussed herein with reference to FIG. 4.

One or more of the scientific instrument 1810, the user local computing device 1820, the service local computing device 1830, and/or the remote computing device 1840 can include a processing device 1802, a storage device 1804, and/or an interface device 1806. The processing device 1802 can take any suitable form, including the form of any of the processors 402 discussed herein with reference to FIG. 4. The processing devices 1802 included in different ones of the scientific instrument 1810, the user local computing device 1820, the service local computing device 1830, and/or the remote computing device 1840 can take the same form or different forms. The storage device 1804 can take any suitable form, including the form of any of the storage devices 404 discussed herein with reference to FIG. 4. The storage devices 1804 included in different ones of the scientific instrument 1810, the user local computing device 1820, the service local computing device 1830, and/or the remote computing device 1840 can take the same form or different forms. The interface device 1806 can take any suitable form, including the form of any of the interface devices 406 discussed herein with reference to FIG. 4. The interface devices 1806 included in different ones of the scientific instrument 1810, the user local computing device 1820, the service local computing device 1830, and/or the remote computing device 1840 can take the same form or different forms.

The scientific instrument 1810, the user local computing device 1820, the service local computing device 1830, and/or the remote computing device 1840 can be in communication with other elements of the scientific instrument system 1800 via communication pathways 1808. The communication pathways 1808 can communicatively couple the interface devices 1806 of different ones of the elements of the scientific instrument system 1800, as shown, and can be wired or wireless communication pathways (e.g., in accordance with any of the communication techniques discussed herein with reference to the interface devices 406 of the computing device 400 of FIG. 4). The particular scientific instrument system 1800 depicted in FIG. 18 includes communication pathways between each pair of the scientific instrument 1810, the user local computing device 1820, the service local computing device 1830, and the remote computing device 1840, but this “fully connected” implementation is simply illustrative, and in various embodiments, various ones of the communication pathways 1808 can be omitted. For example, in one or more embodiments, a service local computing device 1830 can omit a direct communication pathway 1808 between its interface device 1806 and the interface device 1806 of the scientific instrument 1810, but can instead communicate with the scientific instrument 1810 via the communication pathway 1808 between the service local computing device 1830 and the user local computing device 1820 and/or the communication pathway 1808 between the user local computing device 1820 and the scientific instrument 1810.

The scientific instrument 1810 can include any appropriate scientific instrument, such as a separation or MS instrument, or other instrument facilitating material analysis.

The user local computing device 1820 can be a computing device (e.g., in accordance with any of the embodiments of the computing device 400 discussed herein) that is local to a user of the scientific instrument 1810. In one or more embodiments, the user local computing device 1820 can also be local to the scientific instrument 1810, but this need not be the case; for example, a user local computing device 1820 that is associated with a home, office or other building associated with a user entity can be remote from, but in communication with, the scientific instrument 1810 so that the user entity can use the user local computing device 1820 to control and/or access data from the scientific instrument 1810. In one or more embodiments, the user local computing device 1820 can be a laptop, smartphone, or tablet device. In one or more embodiments the user local computing device 1820 can be a portable computing device. In one or more embodiments, the user local computing device 1820 can deployed in the field.

The service local computing device 1830 can be a computing device (e.g., in accordance with any of the embodiments of the computing device 400 discussed herein) that is local to an entity that services the scientific instrument 1810. For example, the service local computing device 1830 can be local to a manufacturer of the scientific instrument 1810 or to a third-party service company. In one or more embodiments, the service local computing device 1830 can communicate with the scientific instrument 1810, the user local computing device 1820, and/or the remote computing device 1840 (e.g., via a direct communication pathway 1808 or via multiple “indirect” communication pathways 1808, as discussed above) to receive data regarding the operation of the scientific instrument 1810, the user local computing device 1820, and/or the remote computing device 1840 (e.g., the results of self-tests of the scientific instrument 1810, calibration coefficients used by the scientific instrument 1810, the measurements of sensors associated with the scientific instrument 1810, etc.). In one or more embodiments, the service local computing device 1830 can communicate with the scientific instrument 1810, the user local computing device 1820, and/or the remote computing device 1840 (e.g., via a direct communication pathway 1808 or via multiple “indirect” communication pathways 1808, as discussed above) to transmit data to the scientific instrument 1810, the user local computing device 1820, and/or the remote computing device 1840 (e.g., to update programmed instructions, such as firmware, in the scientific instrument 1810, to initiate the performance of test or calibration sequences in the scientific instrument 1810, to update programmed instructions, such as software, in the user local computing device 1820 or the remote computing device 1840, etc.). A user entity of the scientific instrument 1810 can utilize the scientific instrument 1810 or the user local computing device 1820 to communicate with the service local computing device 1830 to report a problem with the scientific instrument 1810 or the user local computing device 1820, to request a visit from a technician to improve the operation of the scientific instrument 1810, to order consumables or replacement parts associated with the scientific instrument 1810, or for other purposes.

The remote computing device 1840 can be a computing device (e.g., in accordance with any of the embodiments of the computing device 400 discussed herein) that is remote from the scientific instrument 1810 and/or from the user local computing device 1820. In one or more embodiments, the remote computing device 1840 can be included in a datacenter or other large-scale server environment. In one or more embodiments, the remote computing device 1840 can include network-attached storage (e.g., as part of the storage device 1804). The remote computing device 1840 can store data generated by the scientific instrument 1810, perform analyses of the data generated by the scientific instrument 1810 (e.g., in accordance with programmed instructions), facilitate communication between the user local computing device 1820 and the scientific instrument 1810, and/or facilitate communication between the service local computing device 1830 and the scientific instrument 1810.

In one or more embodiments, one or more of the elements of the scientific instrument system 1800 illustrated in FIG. 18 can be omitted. Further, in one or more embodiments, multiple ones of various ones of the elements of the scientific instrument system 1800 of FIG. 18 can be present. For example, a scientific instrument system 1800 can include multiple user local computing devices 1820 (e.g., different user local computing devices 1820 associated with different user entities or in different locations). In another example, a scientific instrument system 1800 can include multiple scientific instruments 1810, all in communication with service local computing device 1830 and/or a remote computing device 1840; in such an embodiment, the service local computing device 1830 can monitor these multiple scientific instruments 1810, and the service local computing device 1830 can cause updates or other information can be “broadcast” to multiple scientific instruments 1810 at the same time. Different ones of the scientific instruments 1810 in a scientific instrument system 1800 can be located close to one another (e.g., in the same room) or farther from one another (e.g., on different floors of a building, in different buildings, in different cities, etc.). In one or more embodiments, a scientific instrument 1810 can be connected to an Internet-of-Things (IoT) stack that allows for command and control of the scientific instrument 1810 through a web-based application, a virtual or augmented reality application, a mobile application, and/or a desktop application. Any of these applications can be accessed by a user entity operating the user local computing device 1820 in communication with the scientific instrument 1810 by the intervening remote computing device 1840. In one or more embodiments, a scientific instrument 1810 can be sold by the manufacturer along with one or more associated user local computing devices 1820 as part of a local scientific instrument computing unit 1812.

In one or more embodiments, different ones of the scientific instruments 1810 included in a scientific instrument system 1800 can be different types of scientific instruments 1810; for example, one scientific instrument 1810 can be an EDS device, while another scientific instrument 1810 can be an analysis device that analyzes results of an EDS device. In some such embodiments, the remote computing device 1840 and/or the user local computing device 1820 can combine data from different types of scientific instruments 1810 included in a scientific instrument system 1800.

### Example Operating Environment

FIG. 19 is a schematic block diagram of an operating environment 1900 with which the described subject matter can interact. The operating environment 1900 comprises one or more remote component(s) 1910. The remote component(s) 1910 can be hardware and/or software (e.g., threads, processes, computing devices). In one or more embodiments, remote component(s) 1910 can be a distributed computer system, connected to a local automatic scaling component and/or programs that use the resources of a distributed computer system, via communication framework 1940. Communication framework 1940 can comprise wired network devices, wireless network devices, mobile devices, wearable devices, radio access network devices, gateway devices, femtocell devices, servers, etc.

The operating environment 1900 also comprises one or more local component(s) 1920. The local component(s) 1920 can be hardware and/or software (e.g., threads, processes, computing devices). In one or more embodiments, local component(s) 1920 can comprise an automatic scaling component and/or programs that communicate/use the remote resources 1910 and 1920, etc., connected to a remotely located distributed computing system via communication framework 1940.

One possible communication between a remote component(s) 1910 and a local component(s) 1920 can be in the form of a data packet adapted to be transmitted between two or more computer processes. Another possible communication between a remote component(s) 1910 and a local component(s) 1920 can be in the form of circuit-switched data adapted to be transmitted between two or more computer processes in radio time slots. The operating environment 1900 comprises a communication framework 1940 that can be employed to facilitate communications between the remote component(s) 1910 and the local component(s) 1920, and can comprise an air interface, e.g., interface of a UMTS network, via an LTE network, etc. Remote component(s) 1910 can be operably connected to one or more remote data store(s) 1950, such as a hard drive, solid state drive, subscriber identity module (SIM) card, electronic SIM (eSIM), device memory, etc., that can be employed to store information on the remote component(s) 1910 side of communication framework 1940. Similarly, local component(s) 1920 can be operably connected to one or more local data store(s) 1930, that can be employed to store information on the local component(s) 1920 side of communication framework 1940.

### Example Computing Environment

In order to provide additional context for various embodiments described herein, FIG. 20 and the following discussion are intended to provide a brief, general description of a suitable computing environment 2000 in which the various embodiments of the embodiment described herein can be implemented. While the embodiments have been described above in the general context of computer-executable instructions that can run on one or more computers, those skilled in the art will recognize that the embodiments can be also implemented in combination with other program modules and/or as a combination of hardware and software.

Generally, program modules include routines, programs, components, data structures, etc., that perform tasks or implement abstract data types. Moreover, the methods can be practiced with other computer system configurations, including single-processor or multiprocessor computer systems, minicomputers, mainframe computers, Internet of Things (IoT) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can also be practiced in distributed computing environments where certain tasks are performed by remote processing devices that are linked through a communications network. In a distributed computing environment, program modules can be located in both local and remote memory storage devices.

Computing devices typically include a variety of media, which can include computer-readable storage media, machine-readable storage media, and/or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data, or unstructured data.

Computer-readable storage media can include, but are not limited to, random access memory (RAM), read only memory (ROM), electrically erasable programmable read only memory (EEPROM), flash memory or other memory technology, compact disk read only memory (CD ROM), digital versatile disk (DVD), Blu-ray disc (BD) or other optical disk storage, magnetic cassettes, magnetic tape, magnetic disk storage or other magnetic storage devices, solid state drives or other solid state storage devices, or other tangible and/or non-transitory media which can be used to store desired information. In this regard, the terms “tangible” or “non-transitory” herein as applied to storage, memory, or computer-readable media, exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries, or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

Referring still to FIG. 20, the example computing environment 2000 which can implement one or more embodiments described herein includes a computer 2002, the computer 2002 including a processing unit 2004, a system memory 2006 and a system bus 2008. The system bus 2008 couples system components including, but not limited to, the system memory 2006 to the processing unit 2004. The processing unit 2004 can be any of various commercially available processors. Dual microprocessors and other multi processor architectures can also be employed as the processing unit 2004.

The system bus 2008 can be any of several types of bus structure that can further interconnect to a memory bus (with or without a memory controller), a peripheral bus, and a local bus using any of a variety of commercially available bus architectures. The system memory 2006 includes ROM 2010 and RAM 2012. A basic input/output system (BIOS) can be stored in a non-volatile memory such as ROM, erasable programmable read only memory (EPROM), EEPROM, which BIOS contains the basic routines that help to transfer information between elements within the computer 2002, such as during startup. The RAM 2012 can also include a high-speed RAM such as static RAM for caching data.

The computer 2002 further includes an internal hard disk drive (HDD) 2014 (e.g., EIDE, SATA), and can include one or more external storage devices 2016 (e.g., a magnetic floppy disk drive (FDD) 2016, a memory stick or flash drive reader, a memory card reader, etc.). While the internal HDD 2014 is illustrated as located within the computer 2002, the internal HDD 2014 can also be configured for external use in a suitable chassis (not shown). Additionally, while not shown in computing environment 2000, a solid-state drive (SSD) could be used in addition to, or in place of, an HDD 2014.

Other internal or external storage can include at least one other storage device 2020 with storage media 2022 (e.g., a solid-state storage device, a nonvolatile memory device, and/or an optical disk drive that can read or write from removable media such as a CD-ROM disc, a DVD, a BD, etc.). The external storage 2016 can be facilitated by a network virtual machine. The HDD 2014, external storage device 2016 and storage device (e.g., drive) 2020 can be connected to the system bus 2008 by an HDD interface 2024, an external storage interface 2026 and a drive interface 2028, respectively.

The drives and their associated computer-readable storage media provide nonvolatile storage of data, data structures, computer-executable instructions, and so forth. For the computer 2002, the drives and storage media accommodate the storage of any data in a suitable digital format. Although the description of computer-readable storage media above refers to respective types of storage devices, other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 2012, including an operating system 2030, one or more application programs 2032, other program modules 2034 and program data 2036. All or portions of the operating system, applications, modules, and/or data can also be cached in the RAM 2012. The systems and methods described herein can be implemented utilizing various commercially available operating systems or combinations of operating systems.

Computer 2002 can optionally comprise emulation technologies. For example, a hypervisor (not shown) or other intermediary can emulate a hardware environment for operating system 2030, and the emulated hardware can optionally be different from the hardware illustrated in FIG. 20. In such an embodiment, operating system 2030 can comprise one virtual machine (VM) of multiple VMs hosted at computer 2002. Furthermore, operating system 2030 can provide runtime environments, such as the Java runtime environment or the .NET framework, for applications 2032. Runtime environments are consistent execution environments that allow applications 2032 to run on any operating system that includes the runtime environment. Similarly, operating system 2030 can support containers, and applications 2032 can be in the form of containers, which are lightweight, standalone, executable packages of software that include, e.g., code, runtime, system tools, system libraries and settings for an application.

Further, computer 2002 can be enabled with a security module, such as a trusted processing module (TPM). For instance, with a TPM, boot components hash next in time boot components and wait for a match of results to secured values, before loading a next boot component. This process can take place at any layer in the code execution stack of computer 2002, e.g., applied at the application execution level or at the operating system (OS) kernel level, thereby enabling security at any level of code execution.

A user entity can enter commands and information into the computer 2002 through one or more wired/wireless input devices, e.g., a keyboard 2038, a touch screen 2040, and a pointing device, such as a mouse 2042. Other input devices (not shown) can include a microphone, an infrared (IR) remote control, a radio frequency (RF) remote control, or other remote control, a joystick, a virtual reality controller and/or virtual reality headset, a game pad, a stylus pen, an image input device, e.g., camera, a gesture sensor input device, a vision movement sensor input device, an emotion or facial detection device, a biometric input device, e.g., fingerprint or iris scanner, or the like. These and other input devices are often connected to the processing unit 2004 through an input device interface 2044 that can be coupled to the system bus 2008, but can be connected by other interfaces, such as a parallel port, an IEEE 1394 serial port, a game port, a USB port, an IR interface, a BLUETOOTH® interface, etc.

A monitor 2046 or other type of display device can also be connected to the system bus 2008 via an interface, such as a video adapter 2048. In addition to the monitor 2046, a computer typically includes other peripheral output devices (not shown), such as speakers, printers, etc.

The computer 2002 can operate in a networked environment using logical connections via wired and/or wireless communications to one or more remote computers, such as a remote computer 2050. The remote computer 2050 can be a workstation, a server computer, a router, a personal computer, portable computer, microprocessor-based entertainment appliance, a peer device or other common network node, and typically includes many or all of the elements described relative to the computer 2002, although, for purposes of brevity, only a memory/storage device 2052 is illustrated. The logical connections depicted include wired/wireless connectivity to a local area network (LAN) 2054 and/or larger networks, e.g., a wide area network (WAN) 2056. Such LAN and WAN networking environments are commonplace in offices and companies, and facilitate enterprise-wide computer networks, such as intranets, all of which can connect to a global communications network, e.g., the Internet.

When used in a LAN networking environment, the computer 2002 can be connected to the local network 2054 through a wired and/or wireless communication network interface or adapter 2058. The adapter 2058 can facilitate wired or wireless communication to the LAN 2054, which can also include a wireless access point (AP) disposed thereon for communicating with the adapter 2058 in a wireless mode.

When used in a WAN networking environment, the computer 2002 can include a modem 2060 or can be connected to a communications server on the WAN 2056 via other means for establishing communications over the WAN 2056, such as by way of the Internet. The modem 2060, which can be internal or external and a wired or wireless device, can be connected to the system bus 2008 via the input device interface 2044. In a networked environment, program modules depicted relative to the computer 2002 or portions thereof, can be stored in the remote memory/storage device 2052. The network connections shown are example and other means of establishing a communications link between the computers can be used.

When used in either a LAN or WAN networking environment, the computer 2002 can access cloud storage systems or other network-based storage systems in addition to, or in place of, external storage devices 2016 as described above. Generally, a connection between the computer 2002 and a cloud storage system can be established over a LAN 2054 or WAN 2056 e.g., by the adapter 2058 or modem 2060, respectively. Upon connecting the computer 2002 to an associated cloud storage system, the external storage interface 2026 can, with the aid of the adapter 2058 and/or modem 2060, manage storage provided by the cloud storage system as it would other types of external storage. For instance, the external storage interface 2026 can be configured to provide access to cloud storage sources as if those sources were physically connected to the computer 2002.

The computer 2002 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, store shelf, etc.), and telephone. This can include Wireless Fidelity (Wi-Fi) and BLUETOOTH® wireless technologies. Thus, the communication can be a defined structure as with an existing network or simply an ad hoc communication between at least two devices.

### Additional Information

The embodiments described herein can be directed to one or more of a system, a method, an apparatus and/or a computer program product at any possible technical detail level of integration. The computer program product can include a computer readable storage medium (or media) having computer readable program instructions thereon for causing a processor to carry out aspects of the one or more embodiments described herein. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a superconducting storage device and/or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon and/or any suitable combination of the foregoing. A computer readable storage medium, as used herein, is not to be construed as being transitory signals per se, such as radio waves and/or other freely propagating electromagnetic waves, electromagnetic waves propagating through a waveguide and/or other transmission media (e.g., light pulses passing through a fiber-optic cable), and/or electrical signals transmitted through a wire.

Computer readable program instructions described herein can be downloaded to respective computing/processing devices from a computer readable storage medium and/or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the one or more embodiments described herein can be assembler instructions, instruction-set-architecture (ISA) instructions, machine instructions, machine dependent instructions, microcode, firmware instructions, state-setting data, configuration data for integrated circuitry, and/or source code and/or object code written in any combination of one or more programming languages, including an object oriented programming language such as Smalltalk, C++ or the like, and/or procedural programming languages, such as the “C” programming language and/or similar programming languages. The computer readable program instructions can execute entirely on a computer, partly on a computer, as a stand-alone software package, partly on a computer and/or partly on a remote computer or entirely on the remote computer and/or server. In the latter scenario, the remote computer can be connected to a computer through any type of network, including a local area network (LAN) and/or a wide area network (WAN), and/or the connection can be made to an external computer (for example, through the Internet using an Internet Service Provider). In one or more embodiments, electronic circuitry including, for example, programmable logic circuitry, field-programmable gate arrays (FPGA) and/or programmable logic arrays (PLA) can execute the computer readable program instructions by utilizing state information of the computer readable program instructions to personalize the electronic circuitry, in order to perform aspects of the one or more embodiments described herein.

Aspects of the one or more embodiments described herein are described with reference to flowchart illustrations and/or block diagrams of methods, apparatus (systems), and computer program products according to one or more embodiments described herein. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general-purpose computer, special purpose computer and/or other programmable data processing apparatus to produce a machine, such that the instructions, which execute via the processor of the computer or other programmable data processing apparatus, can create means for implementing the functions/acts specified in the flowchart and/or block diagram block or blocks. These computer readable program instructions can also be stored in a computer readable storage medium that can direct a computer, a programmable data processing apparatus and/or other devices to function in a particular manner, such that the computer readable storage medium having instructions stored therein can comprise an article of manufacture including instructions which can implement aspects of the function/act specified in the flowchart and/or block diagram block or blocks. The computer readable program instructions can also be loaded onto a computer, other programmable data processing apparatus and/or other device to cause a series of operational acts to be performed on the computer, other programmable apparatus and/or other device to produce a computer implemented process, such that the instructions which execute on the computer, other programmable apparatus and/or other device implement the functions/acts specified in the flowchart and/or block diagram block or blocks.

The flowcharts and block diagrams in the figures illustrate the architecture, functionality and/or operation of possible implementations of systems, computer-implementable methods and/or computer program products according to one or more embodiments described herein. In this regard, each block in the flowchart or block diagrams can represent a module, segment and/or portion of instructions, which comprises one or more executable instructions for implementing the specified logical function. In one or more alternative implementations, the functions noted in the blocks can occur out of the order noted in the Figures. For example, two blocks shown in succession can be executed substantially concurrently, and/or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that can perform the specified functions and/or acts and/or carry out one or more combinations of special purpose hardware and/or computer instructions.

While the subject matter has been described above in the general context of computer-executable instructions of a computer program product that runs on a computer and/or computers, those skilled in the art will recognize that the one or more embodiments herein also can be implemented at least partially in parallel with one or more other program modules. Generally, program modules include routines, programs, components and/or data structures that perform particular tasks and/or implement particular abstract data types. Moreover, the aforedescribed computer-implemented methods can be practiced with other computer system configurations, including single-processor and/or multiprocessor computer systems, mini-computing devices, mainframe computers, as well as computers, hand-held computing devices (e.g., PDA, phone), and/or microprocessor-based or programmable consumer and/or industrial electronics. The illustrated aspects can also be practiced in distributed computing environments in which tasks are performed by remote processing devices that are linked through a communications network. However, one or more, if not all aspects of the one or more embodiments described herein can be practiced on stand-alone computers. In a distributed computing environment, program modules can be located in both local and remote memory storage devices.

As used in this application, the terms “component,” “system,” “platform” and/or “interface” can refer to and/or can include a computer-related entity or an entity related to an operational machine with one or more specific functionalities. The entities described herein can be either hardware, a combination of hardware and software, software, or software in execution. For example, a component can be, but is not limited to being, a process running on a processor, a processor, an object, an executable, a thread of execution, a program and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system and/or across a network such as the Internet with other systems via the signal). As another example, a component can be an apparatus with specific functionality provided by mechanical parts operated by electric or electronic circuitry, which is operated by a software and/or firmware application executed by a processor. In such a case, the processor can be internal and/or external to the apparatus and can execute at least a part of the software and/or firmware application. As yet another example, a component can be an apparatus that provides specific functionality through electronic components without mechanical parts, where the electronic components can include a processor and/or other means to execute software and/or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter described herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit and/or device comprising, but not limited to, single-core processors; single-processors with software multithread execution capability; multi-core processors; multi-core processors with software multithread execution capability; multi-core processors with hardware multithread technology; parallel platforms; and/or parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, and/or any combination thereof designed to perform the functions described herein. Further, processors can exploit nano-scale architectures such as, but not limited to, molecular and quantum-dot based transistors, switches and/or gates, in order to optimize space usage and/or to enhance performance of related equipment. A processor can be implemented as a combination of computing processing units.

Herein, terms such as “store,” “storage,” “data store,” data storage,” “database,” and substantially any other information storage component relevant to operation and functionality of a component are utilized to refer to “memory components,” entities embodied in a “memory,” or components comprising a memory. Memory and/or memory components described herein can be either volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory and/or nonvolatile random-access memory (RAM) (e.g., ferroelectric RAM (FeRAM). Volatile memory can include RAM, which can act as external cache memory, for example. By way of illustration and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM) and/or Rambus dynamic RAM (RDRAM). Additionally, the described memory components of systems and/or computer-implemented methods herein are intended to include, without being limited to including, these and/or any other suitable types of memory.

What has been described above includes mere examples of systems and computer-implemented methods. It is, of course, not possible to describe every conceivable combination of components and/or computer-implemented methods for purposes of describing the one or more embodiments, but one of ordinary skill in the art can recognize that many further combinations and/or permutations of the one or more embodiments are possible. Furthermore, to the extent that the terms “includes,” “has,” “possesses,” and the like are used in the detailed description, claims, appendices and/or drawings such terms are intended to be inclusive in a manner similar to the term “comprising” as “comprising” is interpreted when employed as a transitional word in a claim.

The descriptions of the various embodiments can use the phrases “an embodiment,” “various embodiments,” “one or more embodiments” and/or “some embodiments,” each of which can refer to one or more of the same or different embodiments.

The descriptions of the various embodiments have been presented for purposes of illustration but are not intended to be exhaustive or limited to the embodiments described herein. Many modifications and variations will be apparent to those of ordinary skill in the art without departing from the scope and spirit of the described embodiments. The terminology used herein was chosen to best explain the principles of the embodiments, the practical application and/or technical improvement over technologies found in the marketplace, and/or to enable others of ordinary skill in the art to understand the embodiments described herein.

What is claimed is:

1. A system, comprising:
a memory that stores computer executable components; and
a processor that executes the computer executable components stored in the memory, wherein the computer executable components comprise:
a beam directing component that instructs a focused ion beam (FIB) device of a beam system to direct an ion beam at a sample support; and
a field application component that affects secondary charged particles, emitted from the sample support due to the ion beam, by directing activation of a negative field from the beam system during application of the ion beam by the FIB device.

2. The system of claim 1, further comprising:
a charged particle detection component that directs registration of the secondary charged particles, which secondary charged particles are received at and detected at the beam system in response to the application of the ion beam by the FIB device to the sample support.

3. The system of claim 2, further comprising:
an image generation component that generates an image of the sample support based on a detection of the secondary charged particles,
wherein, based on the registering of the secondary charged particles, the image comprises a second region having a greater signal than a first region having a lesser signal and that bounds the second region.

4. The system of claim 3, further comprising:
a boundary detection component that identifies a boundary between the first region and the second region, wherein the boundary is defined by an edge of the sample support.

5. The system of claim 3, further comprising:
a fitting component that fits a curve to a boundary between the first region and the second region.

6. The system of claim 3, further comprising:
a patterning component that applies a virtual pattern overlaying an identified portion of the image of the sample support,
wherein the identified portion corresponds to a boundary between the first region and the second region.

7. The system of claim 1, further comprising:
an electron microscope, of the beam system, and the FIB device communicatively coupled to the processor,
wherein the EM comprises a detector that detects the secondary charged particles,
wherein the detector is coupled to or disposed adjacent to a conductive component of the beam system, and
wherein the negative field is applied to the conductive component.

8. A computer-implemented method, comprising:
scanning, by a system operatively coupled to a processor, a sample support with an ion beam of a focused ion beam (FIB) device of a beam system;
generating, by the system, a repulsive charge that repulses, away from a detector of the beam system, a first set of secondary charged particles originating from the sample support based on the scanning; and
allowing, by the system, a second set of secondary charged particles to be registered at the beam system despite the repulsive charge, the second set of secondary charged particles also originating from the sample support based on the scanning.

9. The computer-implemented method of claim 8, further comprising:
generating, by the system, the repulsive charge being a negative field applied to an energy filtering component of the beam system.

10. The computer-implemented method of claim 8,
wherein the second set of secondary charged particles comprises a greater second quantity of secondary charged particles than a first quantity of secondary charged particles comprised by the first set of secondary charged particles.

11. The computer-implemented method of claim 8, further comprising:
causing, by the scanning, emission of the first set of secondary charged particles from a first face of the sample support,
wherein the first face is oriented facing away from the detector; and
causing, by the scanning, emission of the second set of secondary charged particles from a second face of the sample support,
wherein the second face is oriented facing away from the first face and towards the detector.

12. The computer-implemented method of claim 11,
wherein first face is curved, and the second face is planar, and
wherein the first face is contiguous with the second face.

13. The computer-implemented method of claim 8, further comprising:
generating, by the system, an image of the sample support based on receipt of the second set of secondary charged particles at the detector and lack of receipt of the first set of secondary charged particles at the detector.

14. The computer-implemented method of claim 13, further comprising:
identifying, by the system, an edge of the sample support,
wherein the edge is disposed between a second region of the image having greater lesser signal and a first region of the image having a lesser signal,
wherein the second region is generated based on the receipt of the second set of secondary charged particles at the detector, and wherein the first region is generated based on the lack of receipt of the first set of secondary charged particles at the detector.

15. A computer program product facilitating a process for identification of an edge of a sample support by a system associated with a beam system comprising a focused ion beam (FIB) device and an electron microscope (EM), the computer program product comprising a computer readable storage medium having program instructions embodied therewith, and the program instructions executable by a processor to cause the processor to:
register, by the processor, secondary charged particles originating from a sample support aligned relative to the FIB device and the EM; and
generate, by the processor, an image of the sample support, based on the registering,
wherein the image comprises a second region having a greater signal bounded by a first region having a lesser signal, and
wherein a boundary between the first region and the second region corresponds to an edge of the sample support.

16. The computer program product of claim 15, wherein the program instructions are further executable by the processor to cause the processor to:
control, by the processor, the signals of the first region and the second region by controlling, by the processor, activation of a negative field directed towards the sample support.

17. The computer program product of claim 15, wherein the program instructions are further executable by the processor to cause the processor to:
cause, by the processor, repulsion of a first set of the secondary charged particles away from a detector, wherein the repulsion causes the generation of the first region of the image; and
allow, by the processor, receipt of a second set of the secondary charged particles at the detector, wherein the allowing causes the generation of the second region of the image.

18. The computer program product of claim 17,
wherein the second set of secondary charged particles comprises a greater second quantity of secondary charged particles than a first quantity of secondary charged particles comprised by the first set of secondary charged particles.

19. The computer program product of claim 15, wherein the program instructions are further executable by the processor to cause the processor to:
direct, by the processor, generation of an ion beam from the FIB device towards the sample support; and
direct, by the processor, generation of a negative field at the beam system
wherein the generation of the negative field is directed to be at least partially concurrent with the generation of the ion beam from the FIB device.

20. The computer program product of claim 15,
wherein the edge defines a physical delineation between a first face of the sample support and a second face of the sample support, and
wherein the first face is oriented facing away from the second face.
